(19) United States
(12) Patent Application Publication
(10) Pub. No.: US 2024/0136362 A1
(43) Pub. Date: Apr. 25, 2024

(54) THIN FILM TRANSISTOR, METHOD FOR MANUFACTURING THE SAME AND DISPLAY APPARATUS COMPRISING THE SAME

(71) Applicant: LG Display Co., Ltd., Seoul (KR)

(72) Inventors: JeeHo PARK, Paju-si (KR); Sohyung LEE, Paju-si (KR); Hyunki KIM, Paju-si (KR)

(73) Assignee: LG Display Co., Ltd., Seoul (KR)

(21) Appl. No.: 18/378,541

(22) Filed: Oct. 9, 2023

(30) Foreign Application Priority Data
Oct. 24, 2022 (KR) 10-2022-0138478
Apr. 24, 2023 (KR) 10-2023-0053920

(51) Int. Cl. H01L 27/12; H01L 29/786

(52) U.S. Cl. CPC H01L 27/1225; H01L 27/1255; H01L 27/127; H01L 29/78633; H01L 29/7869; H01L 29/78696; H10K 59/1213

(57) ABSTRACT

A thin film transistor can include an active layer; a gate electrode at least partially overlapping with the active layer; and a source electrode and a drain electrode spaced apart from each other and connected to the active layer, respectively. Also, the active layer includes a channel overlapping with the gate electrode; a first connection portion connected to a first side of the channel portion; and a second connection portion connected to a second side of the channel portion. Also, the channel has a crystalline structure, the first connection portion includes a first amorphous portion contacting the channel, and the second connection portion includes a second amorphous portion contacting the channel.

### CROSS-REFERENCE TO RELATED APPLICATIONS

This application claims priority under 35 U.S.C. § 119(a) to Korean Patent Application No. 10-2022-0138478 filed in the Republic of Korea on Oct. 25, 2022, and Korean Patent Application No. 10-2023-0053920 filed in the Republic of Korea on Apr. 25, 2023, the entireties of which are hereby incorporated by reference as if fully set forth herein into the present application.

### BACKGROUND

### Field of the Invention

The present disclosure relates to a thin film transistor, a method for manufacturing the thin film transistor, and a display apparatus including the thin film transistor.

### Discussion of the Related Art

Since a thin film transistor can be manufactured on a glass substrate or a plastic substrate, the thin film transistor has been widely used as a switching element or a driving element of a display apparatus, such as a liquid crystal display apparatus or an organic light emitting device.

The thin film transistor can be categorized into an amorphous silicon thin film transistor in which amorphous silicon is used as an active layer, a polycrystalline silicon thin film transistor in which polycrystalline silicon is used as an active layer, and an oxide semiconductor thin film transistor in which an oxide semiconductor is used as an active layer, based on a material constituting the active layer.

Since amorphous silicon can be deposited to form an active layer in a short time, amorphous silicon thin film transistors (a-Si TFTs) have an advantage of short manufacturing process time and low production costs. On the other hand, amorphous silicon thin film transistors have the disadvantage of being limited in use in active matrix organic light-emitting devices (AMOLEDs) because of their low mobility, poor current driving ability, and changes in threshold voltage.

Polycrystalline silicon thin film transistors (poly-Si TFTs) are made by crystallizing amorphous silicon after amorphous silicon is deposited. Polycrystalline silicon thin film transistors have the advantage of high electron mobility, excellent stability, thin thickness, high resolution, and high power efficiency. These polycrystalline silicon thin film transistors include Low Temperature Poly Silicon (LTPS) thin film transistors or polysilicon thin film transistors. Since a process in which amorphous silicon is crystallized is required in the manufacturing process of a polycrystalline silicon thin film transistor, manufacturing costs increase due to an increase in the number of processes, and crystallization is performed at a high process temperature.

An oxide semiconductor thin film transistor (TFT), which has high mobility and has a large resistance change in accordance with an oxygen content, has an advantage in that desired properties can easily be obtained. Further, since an oxide constituting an active layer can be grown at a relatively low temperature during a process of manufacturing the oxide semiconductor thin film transistor, the manufacturing cost of the oxide semiconductor thin film transistor is reduced. In view of the properties of oxide, since an oxide semiconductor is transparent, it is favorable to embody a transparent display.

Recently, in order to maximize the advantages of oxide semiconductor thin film transistors, studies have been conducted to improve stability and electrical characteristics compared to related art oxide thin film transistors. However, producing oxide thin film transistors can include complex manufacturing steps and increased costs, and damage can occur to the active layer of the thin film transistor and the lifespan of the device may be impaired.

### SUMMARY OF THE DISCLOSURE

The present disclosure has been made in view of the above problems and it is an object of the present disclosure to provide a thin film transistor including an active layer having both a crystalline portion and an amorphous portion.

It is one object of the present disclosure to provide a thin film transistor including an amorphous portion in which a portion of a crystalline oxide semiconductor layer is amorphized by doping with a dopant.

It is another object of the present disclosure to provide a method of manufacturing a thin film transistor including both a crystalline portion and an amorphous portion.

It is still another object of the present disclosure to provide a display apparatus having excellent reliability by including the thin film transistor as described above.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a thin film transistor comprising an active layer, a gate electrode at least partially overlapping the active layer, and a source electrode and a drain electrode spaced apart from each other and connected to the active layer, respectively, and the active layer includes a first active layer, the first active layer includes a channel portion overlapping the gate electrode, a first connection portion connected to one side of the channel portion, and a second connection portion connected to the other side of the channel portion, the channel portion has a crystalline structure, the first connection portion includes a first amorphous portion contacting the channel portion, and the second connection portion includes a second amorphous portion contacting the channel portion.

The channel portion of the first active layer can include at least one crystal structure selected from a cubic crystal structure, a Bixbyite crystal structure, a cubic Bixbyite crystal structure, a spinel crystal structure, a hexagonal crystal structure, and a Wurtzite crystal structure.

The channel portion of the first active layer can have a cubic Bixbyite crystal structure.

The channel portion of the first active layer can include at least one of a (211) crystal plane, a (222) crystal plane, and a (400) crystal plane.

The channel portion of the first active layer can have peaks with respect to a (211) crystal plane, a (222) crystal plane, and a (400) crystal plane in X-ray diffraction analysis (XRD).

The channel portion of the first active layer can include a crystal plane having an inclination angle of 30° to 60° with respect to a horizontal plane.

The first active layer can include an oxide semiconductor material and a crystallization control element dispersed in the oxide semiconductor material.

The crystallization control element can include at least one of beryllium (Be), boron (B), carbon (C), aluminum (Al), silicon (Si), iron (Fe), calcium (Ca), tin (Sn), titanium (Ti), tantalum (Ta), vanadium (V), yttrium (Y), zirconium (Zr), hafnium (Hf), lanthanum (La), and germanium (Ge).

The crystallization control element can be aluminum (Al).

The crystallization control element can have a content of 0.1 to 10 atom % (at %) based on the total number of atoms of the first active layer excluding oxygen.

The crystallization control element can have a content of 0.5 to 6 atom % (at %) based on the total number of atoms of the first active layer excluding oxygen.

The oxide semiconductor material can include at least one of an IZO (InZnO)-based oxide semiconductor material, an IGO (InGaO)-based oxide semiconductor material, an IGZO (InGaZnO)-based oxide semiconductor material, ITO (InSnO)-based oxide semiconductor material, an IGZTO (InGaZnSnO)-based oxide semiconductor material, an ITZO (InSnZnO)-based oxide semiconductor material, a ZnO-based oxide semiconductor material, and a FIZO (FeInZnO)-based oxide semiconductor material.

The first amorphous portion and the second amorphous portion can include a dopant doped by ion injection.

The dopant can include at least one of boron (B), phosphorus (P), fluorine (F), and hydrogen (H).

The first connection portion of the first active layer can further include a first crystalline portion contacting the first amorphous portion, and the second connection portion of the first active layer can further include a second crystalline portion contacting the second amorphous portion.

The first amorphous portion can be disposed between the channel portion and the first crystalline portion, the second amorphous portion can be disposed between the channel portion and the second crystalline portion, and the first crystalline portion and the second crystalline portion can have a same crystal structure with the channel portion.

The first connection portion can further include a third amorphous portion contacting the first crystalline portion, and the first crystalline portion can be disposed between the first amorphous portion and the third amorphous portion.

The second connection portion can further include a fourth amorphous portion contacting the second crystalline portion, and the second crystalline portion can be disposed between the second amorphous portion and the fourth amorphous portion.

The source electrode can be disposed on the same layer as the gate electrode and connected to the first connection portion, and the source electrode can overlap the first crystalline portion and may not overlap the first amorphous portion of the first active layer.

The drain electrode can be disposed on the same layer as the gate electrode and connected to the second connection portion, and the drain electrode can overlap the second crystalline portion and may not overlap the second amorphous portion of the first active layer.

The thin film transistor can further include a first conductive pattern on the first crystalline portion and a second conductive pattern on the second crystalline portion, in which the first conductive pattern may not overlap with the first amorphous portion and the second conductive pattern may not overlap with the second amorphous portion.

The active layer can further include an amorphous active layer overlapping with the first active layer and contacting the first active layer, the amorphous active layer includes a channel portion overlapping with the gate electrode, a first connection portion connected to one side of the channel portion of the amorphous active layer, and a second connection portion connected to the other side of the channel portion of the amorphous active layer, and each of the channel portion, the first connection portion and the second connection portion of the amorphous active layer can have an amorphous structure.

The channel portion of the amorphous active layer can have a carrier concentration lower than a carrier concentration of the channel portion of the first active layer.

The amorphous active layer can have a thickness of 1 to 5 nm.

The first active layer can be disposed between the amorphous active layer and the gate electrode.

The amorphous active layer can be disposed between the first active layer and the gate electrode.

The amorphous active layer can include a first amorphous active layer contacting the first active layer and a second amorphous active layer contacting the first active layer opposite to the first amorphous active layer.

The active layer can further include a barrier active layer overlapping the first active layer and contacting the first active layer, the barrier active layer includes a channel portion overlapping the gate electrode, a first amorphous portion connected to one side of the channel portion of the barrier active layer, and a second amorphous portion connected to the other side of the channel portion of the barrier active layer, the channel portion of the barrier active layer can have a crystalline structure, and each of the first amorphous portion and the second amorphous portion of the barrier active layer can have an amorphous structure.

The channel portion of the barrier active layer can have a carrier concentration lower than a carrier concentration of the channel portion of the first active layer.

The barrier active layer can have a thickness of 5 to 30 nm.

The first active layer can be disposed between the barrier active layer and the gate electrode.

The barrier active layer can be disposed between the first active layer and the gate electrode.

The barrier active layer can include a first barrier active layer contacting the first active layer and a second barrier active layer contacting the first active layer opposite to the first barrier active layer.

The barrier active layer can further include a first crystalline portion contacting the first amorphous portion, and the first amorphous portion can be disposed between the channel portion and the first crystalline portion of the barrier active layer.

The barrier active layer can further include a second crystalline portion contacting the second amorphous portion of the barrier active layer, and the second amorphous portion of the barrier active layer can be disposed between the channel portion and the second crystalline portion of the barrier active layer.

The barrier active layer can further include a third amorphous portion contacting the first crystalline portion of the barrier active layer, and the first crystalline portion of the barrier active layer can be disposed between the first amorphous portion and the third amorphous portion of the barrier active layer.

The barrier active layer can further include a fourth amorphous portion contacting the second crystalline portion of the barrier active layer, and the second crystalline portion of the barrier active layer can be disposed between the second amorphous portion and the fourth amorphous portion of the barrier active layer.

The active layer can further include a barrier active layer disposed opposite to the amorphous active layer to overlap with and contact the first active layer.

Another embodiment of the present disclosure provides a thin film transistor substrate including a base substrate, a light blocking layer on the base substrate, the thin film transistor disposed on the light blocking layer, and a capacitor connected to the light blocking layer, the capacitor includes a first capacitor electrode and a second capacitor electrode, the first capacitor electrode is integrally formed with the light blocking layer, and the second capacitor electrode is disposed on the same layer as the active layer.

The second capacitor electrode can include a layer having an amorphous structure.

The second capacitor electrode can include a layer having a crystalline structure.

The second capacitor electrode can further include a conductive pattern disposed on the layer having the crystalline structure.

The capacitor can further include a third capacitor electrode on a second capacitor electrode, and the third capacitor electrode can be disposed on the same layer as the source electrode and the drain electrode.

The capacitor can further include a third capacitor electrode on the second capacitor electrode, and the third capacitor electrode can be disposed on the same layer as the gate electrode.

Another embodiment of the present disclosure provides a display apparatus including the thin film transistor.

In accordance with another aspect of the present disclosure, the above and other objects can be accomplished by the provision of a method for manufacturing a thin film transistor, which comprises forming an active layer on a substrate, forming a gate insulating layer on the active layer, forming a gate electrode on the gate insulating layer, and selectively doping the active layer with a dopant, in which the forming the active layer includes forming a first oxide semiconductor material layer using a crystalline oxide semiconductor material, forming an active pattern by patterning the first oxide semiconductor material layer, and forming a first active layer having a crystalline active pattern by heat-treating the active pattern, and a region doped with the dopant in the active layer has an amorphous structure.

The first oxide semiconductor material layer can include an oxide semiconductor material and a crystallization control element.

The crystallization control element can include at least one of beryllium (Be), boron (B), carbon (C), aluminum (Al), silicon (Si), iron (Fe), calcium (Ca), titanium (Ti), tantalum (Ta), vanadium (V), yttrium (Y), zirconium (Zr), hafnium (Hf), lanthanum (La), and germanium (Ge).

The forming the active layer can further include forming an amorphous oxide semiconductor material layer using an amorphous oxide semiconductor material.

The forming of the active layer can further include forming a barrier oxide semiconductor material layer using a crystalline oxide semiconductor material.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a cross-sectional view of a thin film transistor according to an embodiment of the present disclosure.

FIG. 2 is a schematic diagram of a cubic Bixbyite crystal structure according to an embodiment of the present disclosure.

FIG. 3 is an X-ray diffraction analysis (XRD) graph of a channel portion of a first active layer according to an embodiment of the present disclosure.

FIG. 4 is a transmission electron microscope (TEM) photograph of a channel portion of a first active layer according to an embodiment of the present disclosure.

FIG. 5 is a cross-sectional view of a thin film transistor according to another embodiment of the present disclosure.

FIG. 6 is a cross-sectional view of a thin film transistor according to another embodiment of the present disclosure.

FIG. 7 is a cross-sectional view of a thin film transistor according to another embodiment of the present disclosure.

FIG. 8 is a cross-sectional view of a thin film transistor according to another embodiment of the present disclosure.

FIG. 9 is a cross-sectional view of a thin film transistor according to another embodiment of the present disclosure.

FIG. 10 is a cross-sectional view of a thin film transistor according to another embodiment of the present disclosure.

FIG. 11 is a cross-sectional view of a thin film transistor according to another embodiment of the present disclosure.

FIG. 12 is a cross-sectional view of a thin film transistor according to another embodiment of the present disclosure.

FIG. 13 is a cross-sectional view of a thin film transistor according to another embodiment of the present disclosure.

FIG. 14 is a cross-sectional view of a thin film transistor according to another embodiment of the present disclosure.

FIG. 15 is a cross-sectional view of a thin film transistor according to another embodiment of the present disclosure.

FIG. 16 is a cross-sectional view of a thin film transistor according to another embodiment of the present disclosure.

FIG. 17 is a cross-sectional view of a thin film transistor according to another embodiment of the present disclosure.

FIG. 18 is a cross-sectional view of a thin film transistor according to another embodiment of the present disclosure.

FIG. 19 is a cross-sectional view of a thin film transistor substrate according to another embodiment of the present disclosure.

FIG. 20 is a cross-sectional view of a thin film transistor substrate according to another embodiment of the present disclosure.

FIG. 21 is a cross-sectional view of a thin film transistor substrate according to another embodiment of the present disclosure.

FIG. 22 is a cross-sectional view of a thin film transistor substrate according to another embodiment of the present disclosure.

FIG. 23 is a cross-sectional view of a thin film transistor substrate according to another embodiment of the present disclosure.

FIG. 24 is a schematic view of a display apparatus according to another embodiment of the present disclosure.

FIG. 25 is a circuit diagram of any one pixel of FIG. 24 according to an embodiment of the present disclosure.

FIG. 26 is a plan view of a pixel of FIG. 25 according to an embodiment of the present disclosure.

FIG. 27 is a cross-sectional view taken along line I-I′ of FIG. 26 according to an embodiment of the present disclosure.

FIG. 28 is a circuit diagram of any one pixel of a display apparatus according to another embodiment of the present disclosure.

FIG. 29 is a circuit diagram of any one pixel of a display apparatus according to another embodiment of the present disclosure.

FIG. 30 is a circuit diagram of any one pixel of a display apparatus according to another embodiment of the present disclosure.

### DETAILED DESCRIPTION OF THE EMBODIMENTS

Advantages and features of the present disclosure and implementation methods thereof will be clarified through the following embodiments described with reference to the accompanying drawings. The present disclosure can, however, be embodied in different forms and should not be construed as limited to the embodiments set forth herein. Rather, these embodiments are provided so that this disclosure will be thorough and complete and will fully convey the scope of the present disclosure to those skilled in the art.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a situation where “comprise,” “have” and “include” described in the present disclosure are used, another portion can be added unless “only” is used. The terms of a singular form can include plural forms unless referred to the contrary.

In construing an element, the element is construed as including an error band although there is no explicit description.

In describing a position relationship, for example, when the position relationship is described as “upon” “above,” “below” and “next to,” one or more portions can be disposed between two other portions unless ‘just’ or ‘direct’ is used.

Spatially relative terms such as “below,” “beneath,” “lower,” “above,” and “upper” can be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below,” or “beneath” another device can be arranged “above” another device. Therefore, an exemplary term “below or beneath” can include “below or beneath” and “above” orientations. Likewise, an exemplary term “above” or “on” can include “above” and “below or beneath” orientations.

In describing a temporal relationship, for example, when the temporal order is described as “after,” “subsequent,” “next,” and “before,” a situation which is not continuous can be included, unless “just” or “direct” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related to any one item. For example, “at least one among a first element, a second element and a third element” can include all combinations of two or more elements selected from the first, second and third elements as well as each element of the first, second and third elements.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode can be interchanged. The source electrode can be the drain electrode and vice versa. In addition, the source electrode of any one embodiment can be a drain electrode in another embodiment, and the drain electrode of any one embodiment can be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area can be the source electrode, and the drain area can be the drain electrode. In addition, the source area can be the drain electrode, and the drain area can be the source electrode. In addition, in some embodiments of the present disclosure, the term “channel” may mean “channel portion,” and the term “channel portion” may mean “channel.”

FIG. 1 is a cross-sectional view of a thin film transistor 100 according to an embodiment of the present disclosure.

The thin film transistor 100 according to the embodiment of this disclosure includes an active layer ACT on the substrate 110, a gate electrode 150 that at least partially overlaps with the active layer ACT, and a source electrode 160 and a drain electrode 170 separated from each other, and connected to the active layer, respectively. The active layer ACT includes a channel portion CN, a first connection portion CON1 connected to one side of the channel portion CN, and a second connection portion CON2 connected to the other side of the channel portion CN. The channel portion CN overlaps with the gate electrode 150. In the embodiments of the present disclosure, the channel portion can be referred to as “channel,” and the channel portion CN may be referred to as “channel CN.”

The thin film transistor 100 can be disposed on the substrate 110. As long as a layer or element supports the thin film transistor 100, it can be referred to as the substrate 110 without limitation.

Glass or plastic can be used as the substrate 110. Transparent plastic having flexible properties for example, polyimide as plastic, can be used. When polyimide is used as a substrate 110, heat-resistant polyimide that can withstand high temperatures can be used considering that a high-temperature deposition process is performed on the substrate 110.

The light blocking layer 111 can be disposed on the substrate 110. The light blocking layer 111 overlaps with the channel portion CN. The light blocking layer 111 blocks light incident from the outside to protect the channel portion CN.

The light blocking layer 111 can be made of a material having light blocking properties. The light blocking layer 111 can include at least one of aluminum-based metals such as aluminum (Al) or aluminum alloys, molybdenum-based metals such as molybdenum (Mo) or molybdenum alloys, chromium (Cr), tantalum (Ta), neodymium (Nd), titanium (Ti), and iron (Fe). According to an embodiment of the present disclosure, the light blocking layer 111 can have electrical conductivity.

The light blocking layer 111 can be electrically connected to any one of the source electrode 160 and the drain electrode 170. The light blocking layer 111 can be omitted.

A buffer layer 112 is disposed on the light blocking layer 111. The buffer layer 112 can be made of an insulating material. For example, the buffer layer 112 can include at least one of various insulating materials, such as silicon oxide, silicon nitride, and metal-based oxide. The buffer layer 112 can have a single layer structure or a multilayer layer structure.

The buffer layer 112 can protect the active layer ACT by blocking air and moisture. In addition, the surface of the upper part of the substrate 110 on which the light blocking layer 111 is disposed can be made uniform or planarized by the buffer layer 112.

The active layer ACT is disposed on the buffer layer 112.

According to an embodiment of the present disclosure, the active layer ACT can be formed of a semiconductor material. The active layer ACT can include, for example, an oxide semiconductor layer.

Referring to FIG. 1, the active layer ACT includes a first active layer 130. FIG. 1 illustrates a structure in which the active layer ACT is formed by the first active layer 130. The first active layer 130 is an oxide semiconductor layer.

The first active layer 130 can include an oxide semiconductor material and a crystallization control element dispersed in the oxide semiconductor material.

The first active layer 130 can include a crystalline oxide semiconductor material. The oxide semiconductor material contained in the first active layer 130 can include, for example, at least one of an IZO (InZnO)-based oxide semiconductor material, an IGO (InGaO)-based oxide semiconductor material, an IGZO (InGaZnO)-based oxide semiconductor material, ITO (InSnO)-based oxide semiconductor material, an IGZTO (InGaZnSnO)-based oxide semiconductor material, an ITZO (InSnZnO)-based oxide semiconductor material, a ZnO-based oxide semiconductor material, and a FIZO (FeInZnO)-based oxide semiconductor material. However, one embodiment of this disclosure is not limited to this, and the first active layer 130 can be made of other oxide semiconductor materials with crystallinity and high mobility.

According to an embodiment of this disclosure, as an oxide semiconductor material for forming the first active layer 130, for example, an indium-based oxide semiconductor material having an indium (In) content of 50% or more based on the number of atoms can be used. For example, the first active layer 130 can include at least one of an IZO (InZnO)-based oxide semiconductor material, an IGO (InGaO)-based oxide semiconductor material, an IGZO (InGaZnO)-based oxide semiconductor material, and an ITO (InSnO)-based oxide semiconductor material with an indium (In) content of 50% (at %) or more among the total metal elements.

More specifically, as an oxide semiconductor material for forming the first active layer 130, IZO (InZnO)-based oxide semiconductor material having the ratio (In:Zn) of indium (In) to zinc (Zn) of 5:5, 6:4, 7:3, 8:2 or 9:1, IGO (InGaO)-based oxide semiconductor material having an indium (In) to gallium (Ga) ratio (In:Ga) of 7:3, 8:2, or 9:1, IGZO (InGaZnO)-based oxide semiconductor material in which the ratio of indium (In) and “zinc (Zn)+gallium (Ga)” [In:(Zn+Ga)] is 5:5, 6:4, 7:3 or 8:2, and an ITO (InSnO)-based oxide semiconductor material having an indium (In) to tin (Sn) ratio (In:Sn) of 5:5, 6:4, 7:3, 8:2 or 9:1 can be used.

According to one embodiment of this disclosure, since the first active layer 130 contains a high concentration of indium (In), the channel portion CN can have high mobility characteristics, and the thin film transistor 100 can have excellent electrical characteristics. For example, the first active layer 130 can have a mobility of 40 cm²/V s or more.

In addition, according to an embodiment of the present disclosure, indium (In) is included in the first active layer 130 at a high concentration, but since the first active layer 130 includes both crystalline and amorphous portions, the thin film transistor 100 can have excellent driving stability and reliability.

According to an embodiment of the present disclosure, the first active layer 130 can include a crystallization control element dispersed in an oxide semiconductor material.

The crystallization control element can include at least one of beryllium (Be), boron (B), carbon (C), aluminum (Al), silicon (Si), iron (Fe), calcium (Ca), tin (Sn), titanium (Ti), tantalum (Ta), vanadium (V), yttrium (Y), zirconium (Zr), hafnium (Hf), lanthanum (La), and germanium (Ge).

The crystallization control element is an element having a large binding force with oxygen, and can delay the crystallization rate of the first active layer 130. The first active layer 130 can be formed by deposition and patterning, and the crystallization control element prevents crystallization of the first active layer 130 during the deposition process, thereby preventing the patterning of the first active layer 130.

On the other hand, the crystallization control element does not prevent crystallization of the first active layer 130 by heat treatment. As a result, the first active layer 130 can be crystallized in a heat treatment process after patterning for forming the first active layer 130.

According to an embodiment of the present disclosure, aluminum (Al) can be used as a crystallization control element. When the first active layer 130 contains a small amount of aluminum (Al), crystallization of the first active layer 130 can be prevented during the deposition process, and the first active layer 130 can be crystallized by the heat treatment process.

According to an embodiment of this disclosure, the crystallization control element can have a content of 0.1 to 10% by atom (at %) with respect to the total number of atoms of the first active layer 130 excluding oxygen. When the content of the crystallization control element is less than 0.1 atom % (at %) with respect to the total number of atoms of the first active layer 130 excluding oxygen, a crystallization prevention effect may not be sufficiently exhibited during the deposition process and crystallization may occur during deposition. As a result, difficulties can occur in the process of patterning after depositing the oxide semiconductor material for forming the first active layer 130. In other words, if the forming the first active layer 130 is crystallized during the deposition process, then it may be difficult or costly to selectively pattern portions of the first active layer 130 at a later patterning step.

On the other hand, when the content of the crystallization control element exceeds 10 atom % (at %) with respect to the total number of atoms of the first active layer 130 excluding oxygen, the first active layer 130 may not crystallize or the crystallization rate can decrease due to excessive crystallization control elements.

In more detail, according to an embodiment of the present disclosure, the crystallization control element can have a content of 0.5 to 6 atom % (at %) with respect to the total number of atoms of the first active layer excluding oxygen.

According to an embodiment of the present disclosure, the active layer ACT of the thin film transistor 100 includes a channel portion CN, a first connection portion CON1, and a second connection portion CON2. Referring to FIG. 1, an active layer ACT can be formed by the first active layer 130.

According to an embodiment of the present disclosure, the first active layer 130 can be made of a crystalline oxide semiconductor material. A specific portion of the first active layer 130 can be selectively conductorized, and the selectively conductorized portion can have excellent electrical conductivity to become a connection portion. In addition, the selectively conductorized portion can have an amorphous structure.

The selective conduction (e.g., conductorization) refers to improving the conductivity of a selected portion of the first active layer 130 or providing conductivity to the selected portion. According to an embodiment of the present disclosure, selective conduction can be performed by doping with a dopant in a selected region. In addition, first and second amorphous portions 130a and 130b can be formed by dopant doping, dopant injection or injection of dopant ion.

According to an embodiment of the present disclosure, doping can be performed by injecting dopant ions. The first amorphous portion 130a and the second amorphous portion 130b can include a dopant doped by ion implantation.

According to an embodiment of the present disclosure, the dopant can include at least one of boron (B), phosphorus (P), fluorine (F), and hydrogen (H).

According to an embodiment of this disclosure, the first active layer 130 is formed by a crystalline oxide semiconductor material, and selected portions of the first active layer 130 are doped by dopant injection or ion injection, so that the first amorphous portion 130a and the second amorphous portion 130b can be formed. Ion injection means injection or implantation of dopant ions.

The first amorphous portion 130a and the second amorphous portion 130b formed by dopant doping are conductive portions (e.g., conductorized portions) and can have excellent electrical conductivity. As a result, the first amorphous portion 130a can be a first connection portion CON1, and the second amorphous portion 130b can be a second connection portion CON2.

With this configuration, as illustrated in FIG. 1, the first active layer 130 can include a channel portion 130n, a first connection portion CON1, and a second connection portion CON2. In the embodiments of the present disclosure, the channel portion can be referred to as “channel,” and the channel portion 130n may be referred to as “channel 130n.”

The channel portion 130n of the first active layer 130 is a region overlapping with the gate electrode 150. The first connection portion CON1 is connected to one side of the channel portion 130n, and the second connection portion CON2 is connected to the other side of the channel portion 130n. In addition, the first connection portion CON1 of the first active layer 130 can include the first amorphous portion 130a, and the second connection portion CON2 can include the second amorphous portion 130b.

According to an embodiment of this disclosure, each of the first amorphous portion 130a and the second amorphous portion 130b can be a portion containing more dopants than the channel portion 130n. For example, the first amorphous portion 130a and the second amorphous portion 130b can be more conductive or have less resistance than the channel portion 130n.

A portion of the first active layer 130 that is not doped with dopants and is not conductorized can be the channel portion 130n.

Referring to FIG. 1, doping can be performed using the gate electrode 150 as a mask, and as a result, a portion of the first active layer 130 overlapping the gate electrode 150 may not be doped to become a channel portion 130n.

By doping with a dopant, the boundary of the channel portion 130n can be clarified or better defined. In addition, dopant doping can improve the electrical connection characteristics between the source electrode 160 and the channel portion 130n and between the drain electrode 170 and the channel portion 130n.

Since the active layer ACT is formed by the first active layer 130, the channel portion 130n of the first active layer 130 becomes the channel portion CN of the active layer ACT, the first amorphous portion 130a of the first active layer 130 becomes the first connection portion CON1 of the active layer ACT, and the second amorphous portion 130b of the first active layer 130 becomes the second connection portion CON2 of the active layer ACT.

By selective conduction (e.g., conductorization) of the first active layer 130, the channel portion 130n, the first connection portion, and the second connection portion can be distinguished from each other.

The channel portion 130n of the first active layer 130 overlaps with the gate electrode 150. The channel portion 130n is a non-conductive portion or the channel portion 130n can be less conductive than the first amorphous portion 130a and the second amorphous portion 130b.

According to an embodiment of the present disclosure, the first active layer 130 can be made of a crystalline oxide semiconductor material, and the non-conductive channel portion 130n (e.g., non-conductorized channel portion 130n) can have a crystalline structure.

The channel portion 130n having a crystalline structure can have excellent physical and chemical stability. As a result, damage to the channel portion 130n or deformation of the physical properties of the channel portion 130n can be prevented during the manufacturing and use of the thin film transistor 100. Accordingly, the thin film transistor 100 according to an embodiment of the present disclosure can have excellent driving stability and the lifespan can be increased.

According to an embodiment of this disclosure, the channel portion 130n of the first active layer 130 can include at least one of a cubic crystal structure, a Bixbyite crystal structure, a cubic Bixbyite crystal structure, a spinel crystal structure, a hexagonal crystal structure, and a Wurtzite crystal structure, but embodiments are not limited thereto.

More specifically, the channel portion 130n of the first active layer 130 according to an embodiment of the present disclosure can have, for example, a cubic Bixbyite crystal structure.

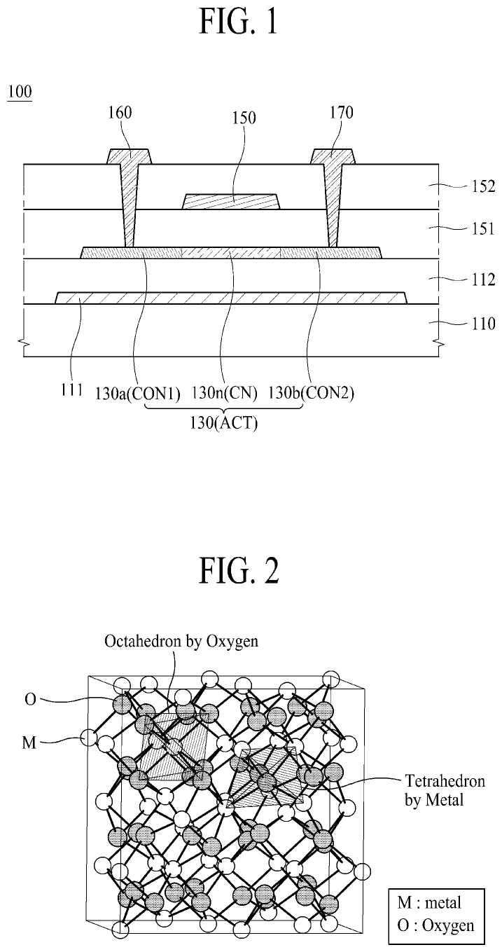

FIG. 2 is a schematic diagram of a cubic Bixbyite crystal structure.

Referring to FIG. 2, an oxygen atom O is disposed inside an octahedron formed by a metal atom M included in the first active layer 130, and a metal atom M is disposed inside a tetrahedron formed by the oxygen atom O to form a cubic Bixbyite crystal structure.

According to an embodiment of this disclosure, a cubic Bixbyite crystal structure can be formed by metal atoms and oxygen atoms included in the first active layer 130, and the crystallization control element can be dispersed at a low concentration in the cubic Bixbyite crystal structure. Therefore, the channel portion 130n of the first active layer 130 can include a crystallization control element dispersed in the cubic Bixbyite crystal structure and the cubic Bixbyite crystal structure formed by metal atoms and oxygen atoms.

According to an embodiment of the present disclosure, the channel portion 130n of the first active layer 130 can have a crystal plane. The channel portion 130n of the first active layer 130 can include at least one of a (211) crystal plane, a (222) crystal plane, and a (400) crystal plane. For example, the channel portion 130n of the first active layer 130 can have a (222) crystal plane.

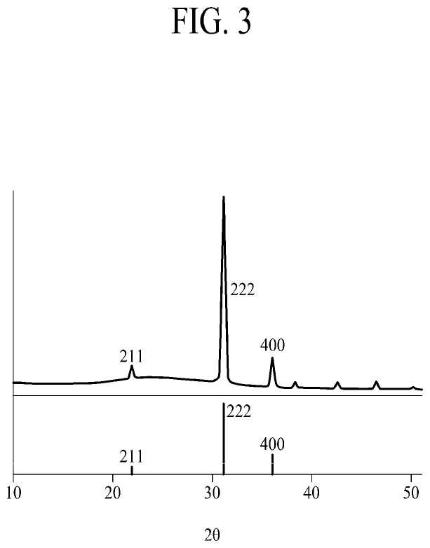

FIG. 3 is an X-ray diffraction analysis (XRD) graph of the channel portion 130n of the first active layer 130.

According to an embodiment of the present disclosure, when X-ray diffraction analysis (XRD) is performed in a range of a diffraction angle (2θ) of 10° to 50°, an XRD graph having peaks corresponding to crystal planes can be obtained. According to the X-ray diffraction analysis (XRD) graph shown in FIG. 3, peaks corresponding to the (211) crystal plane, (222) crystal plane, and (400) crystal plane are detected. Accordingly, the channel portion 130n of the first active layer 130 can have a (211) crystal plane, a (222) crystal plane, and a (400) crystal plane.

In addition, referring to FIG. 3, the peak of the (222) crystal plane is the largest in the X-ray diffraction analysis (XRD) graph for the channel portion 130n of the first active layer 130. Accordingly, it can be said that the (222) crystal plane is mainly formed in the channel portion 130n of the first active layer 130. For example, a number of portions within the channel portion 130n having the (222) crystal plane can be greater than a number of portions within the channel portion 130n having the (400) crystal plane, and the number of portions within the channel portion 130n having the (400) crystal plane can be greater than that a number of portions within the channel portion 130n having the (221) crystal plane.

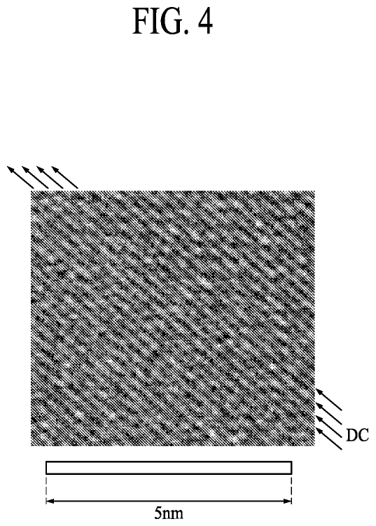

FIG. 4 is a transmission electron microscope (TEM) photograph of the channel portion 130n of the first active layer 130.

Referring to FIG. 4, it can be seen that the channel portion 130n of the first active layer 130 includes a crystal plane with an inclination angle of 30° to 60° to the horizontal surface (e.g., 45°). According to an embodiment of the present disclosure, the horizontal plane is a plane parallel to the upper surface of the channel portion 130n of the first active layer 130. According to an embodiment of the present disclosure, the horizontal plane can be parallel to the bottom surface of the gate electrode 150. In FIG. 4, “DC” indicates the direction of inclination.

Referring to FIG. 1, a gate insulating layer 151 is disposed on the first active layer 130 which is the active layer ACT of the thin film transistor 100. The gate insulating layer 151 can include at least one of silicon oxide, silicon nitride, and metal-based oxide. The gate insulating layer 151 can have a single layer structure or a multilayer layer structure. The gate insulating layer 151 protects the channel portion CN.

Referring to FIG. 1, the gate insulating layer 151 can be integrally formed on the substrate 110. For example, the gate insulating layer 151 can cover all of the channel portion CN, the first connection portion CON1, and the second connection portion CON2 except for the contact area (e.g., where the contact holes are).

However, an embodiment of the present disclosure is not limited thereto, and the gate insulating layer 151 can be patterned. For example, the gate insulating layer 151 can be patterned in a shape corresponding to the gate electrode 150. For example, a length of the gate insulating layer 151 can be equal to a length of the gate electrode 150.

The gate electrode 150 is disposed on the gate insulating layer 151. The gate electrode 150 overlaps with the channel portion 130n of the first active layer 130, which is the channel portion CN of the thin film transistor 100.

The gate electrode 150 can include at least one of aluminum-based metals such as aluminum (Al) or aluminum alloys, silver-based metals such as silver (Ag) or silver alloys, copper-based metals such as copper (Cu) or copper alloys, molybdenum-based metals such as molybdenum (Mo) or molybdenum alloys, chromium (Cr), tantalum (Ta), neodymium (Nd), and titanium (Ti). Each of the gate electrodes 150 can have a multilayer structure including at least two conductive layers having different physical properties.

Referring to FIG. 1, an interlayer insulating layer 152 is disposed on the gate insulating layer 151 and the gate electrode 150. The interlayer insulating layer 152 is an insulating layer made of an insulating material. The interlayer insulating layer 152 can be made of an organic material, an inorganic material, or a laminate of an organic material layer and an inorganic material layer. The source electrode 160 and the drain electrode 170 can be disposed on the interlayer insulating layer 152.

The source electrode 160 and the drain electrode 170 can each include at least one of molybdenum (Mo), aluminum (Al), chromium (Cr), gold (Au), titanium (Ti), nickel (Ni), neodymium (Nd), copper (Cu), and alloys thereof. Each of the source electrode 160 and drain electrode 170 can be composed of a single layer made of a metal or an alloy of metal, or can be composed of two or more layers.

According to an embodiment of the present disclosure, the source electrode 160 can be connected to the first connection portion CON1. Specifically, the source electrode 160 can be electrically connected to the first amorphous portion 130a of the first active layer 130 through a contact hole. As a result, the source electrode 160 can be connected to the active layer ACT to transmit an electrical signal to the channel portion CN.

The drain electrode 170 can be spaced apart from the source electrode 160 and connected to the second connection portion CON2. Specifically, the drain electrode 170 can be electrically connected to the second amorphous portion 130b of the first active layer 130 through a contact hole. As a result, the drain electrode 170 can be connected to the active layer ACT to transmit an electrical signal to the channel portion CN.

In the thin film transistor 100 according to FIG. 1, the first amorphous portion 130a in contact with the channel portion 130n of the first active layer 130 can be the first connection portion CON1. In addition, the second amorphous portion 130b in contact with the channel portion 130n of the first active layer 130 can be the second connection portion CON2.

According to an embodiment of the present disclosure, the first connection portion CON1 of the active layer ACT can be a source region, and the second connection portion CON2 can be a drain region. According to an embodiment of the present disclosure, the first connection portion CON1 can serve as a source electrode, and the second connection portion CON2 can serve as a drain electrode. The first connection portion CON1 and the second connection portion CON2 can be changed from each other.

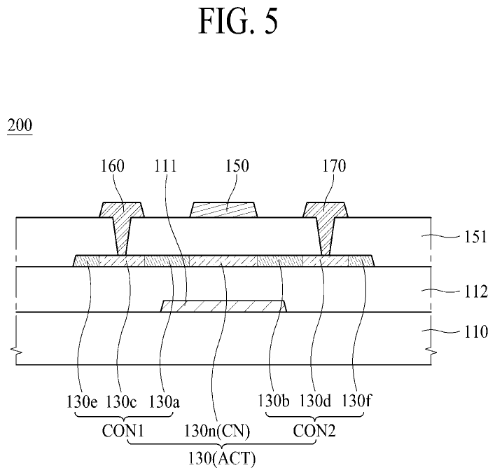

FIG. 5 is a cross-sectional view of a thin film transistor 200 according to another embodiment of the present disclosure.

Referring to FIG. 5, an active layer ACT of the thin film transistor 200 according to another embodiment of the present disclosure includes a first active layer 130. The first active layer 130 becomes the active layer ACT of the thin film transistor 200.

The first connection portion CON1 of the first active layer 130 can further include a first crystalline portion 130c in contact with the first amorphous portion 130a. In addition, the second connection portion CON2 of the first active layer 130 can further include a second crystalline portion 130d in contact with the second amorphous portion 130b. The first amorphous portion 130a can be disposed between the channel portion 130n and the first crystalline portion 130c. The second amorphous portion 130b can be disposed between the channel portion 130n and the second crystalline portion 130d.

The first crystalline portion 130c and the second crystalline portion 130d are portions that are not doped during the doping process of the first active layer 130. More specifically, during the doping process for the first active layer 130, the dopant is blocked by the source electrode 160 and the drain electrode 170, so that the undoped portion can become the first crystalline portion 130c and the second crystalline portion 130d. The first crystalline portion 130c and the second crystalline portion 130d can have the same crystal structure as the channel portion 130n. For example, the source electrode 160, the drain electrode 170 and the gate electrode 150 can be used as a mask during the doping process.

The first crystalline portion 130c can overlap with the source electrode 160, and the second crystalline portion 130d can overlap with the drain electrode 170. However, embodiments this disclosure are not limited to this, and the first crystalline portion 130c can overlap with the drain electrode 170, and the second crystalline portion 130d can overlap with the source electrode 160.

Referring to FIG. 5, the first crystalline portion 130c overlaps with the source electrode 160. In the process of forming a contact hole connecting the source electrode 160 and the first connection portion CON1, the first crystalline portion 130c can be conductive (e.g., conductorized). As a result, since electrical contact between the source electrode 160 and the first crystalline portion 130c is smoothly made, electrical contact between the source electrode 160 and the first connection portion CON1 can be smoothly made.

Referring to FIG. 5, the second crystalline portion 130d overlaps with the drain electrode 170. In the process of forming a contact hole connecting the drain electrode 170 and the second connection portion CON2, the second crystalline portion 130d can be conductive (e.g., conductorized). As a result, since electrical contact between the drain electrode 170 and the second crystalline portion 130d is smoothly made, electrical contact between the drain electrode 170 and the second connection portion CON2 can be made smoothly.

In accordance with another embodiment of this disclosure, the first connection portion CON1 can further include a third amorphous portion 130e in contact with the first crystalline portion 130c. As shown in FIG. 1, the first crystalline portion 130c can be disposed between the first amorphous portion 130a and the third amorphous portion 130e.

Referring to FIG. 5, the third amorphous portion 130e does not overlap with the gate electrode 150, the source electrode 160, and the drain electrode 170.

The second connection portion CON2 can further include a fourth amorphous portion 130f in contact with the second crystalline portion 130d. The second crystalline portion 130d can be disposed between the second amorphous portion 130b and the fourth amorphous portion 130f.

Referring to FIG. 5, the fourth amorphous portion 130f does not overlap with the gate electrode 150, the source electrode 160, and the drain electrode 170.

Referring to FIG. 5, the first connection portion CON1 can include a first amorphous portion 130a, a first crystalline portion 130c, and a third amorphous portion 130e. The second connection portion CON2 can include a second amorphous portion 130b, a second crystalline portion 130d, and a fourth amorphous portion 130f.

Referring to FIG. 5, the source electrode 160 and the drain electrode 170 are disposed on the gate insulating layer 151. The source electrode 160 and the drain electrode 170 can be disposed on the same layer as the gate electrode 150. The source electrode 160 and the drain electrode 170 can be made of the same material as the gate electrode 150 and can be made by the same process.

Referring to FIG. 5, the source electrode 160 overlaps with the first crystalline portion 130c and does not overlap with the first amorphous portion 130a. In addition, the source electrode 160 does not overlap with the third amorphous portion 130e. Among the first active layer 130, an area where dopant doping is blocked by the source electrode 160 during the doping process using a dopant becomes the first crystalline portion 130c.

Referring to FIG. 5, the drain electrode 170 overlaps the second crystalline portion 130d and does not overlap with the second amorphous portion 130b. In addition, the drain electrode 170 does not overlap with the fourth amorphous portion 130f. Among the first active layer 130, the region where dopant doping is blocked by the drain electrode 170 during the doping process using the dopant becomes the second crystalline portion 130d.

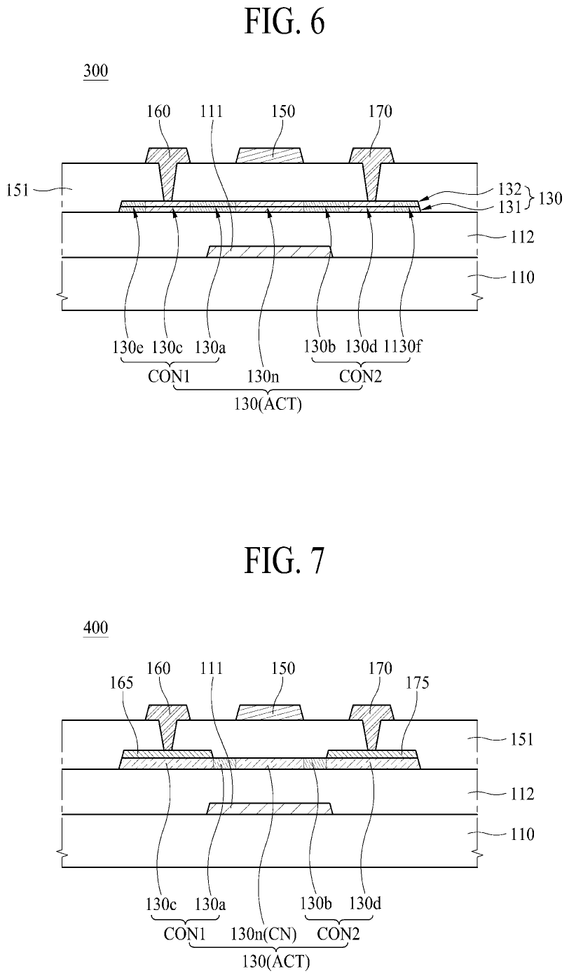

FIG. 6 is a cross-sectional view of a thin film transistor 300 according to another embodiment of the present disclosure. Compared to the thin film transistor 200 of FIG. 5, the first active layer 130 has a multilayer structure in the thin film transistor 300 of FIG. 6. As a result, the active layer ACT can have a multilayer structure (e.g., a dual layer structure).

Referring to FIG. 6, the first active layer 130 includes a first oxide semiconductor layer 131 and a second oxide semiconductor layer 132 on the first oxide semiconductor layer 131. The first oxide semiconductor layer 131 and the second oxide semiconductor layer 132 can include the same semiconductor material or can include different semiconductor materials.

The first oxide semiconductor layer 131 supports the second oxide semiconductor layer 132. Accordingly, the first oxide semiconductor layer 131 is also referred to as a support layer. The main channel portion can be formed on the second oxide semiconductor layer 132. Accordingly, the second oxide semiconductor layer 132 can be referred to as a “channel layer.” However, an embodiment of the present disclosure is not limited thereto, and a main channel portion can be formed on the first oxide semiconductor layer 131.

According to another embodiment of the present disclosure, both the first oxide semiconductor layer 131 and the second oxide semiconductor layer 132 can have crystallinity. The active layer ACT or the first active layer 130 has a structure composed of two layers, and is also referred to as a bi-layer structure or a dual-layer structure.

FIG. 7 is a cross-sectional view of a thin film transistor 400 according to another embodiment of the present disclosure. The thin film transistor 400 of FIG. 7 includes a first conductive pattern 165 on the first crystalline portion 130c and a second conductive pattern 175 on the second crystalline portion 130d.

According to another embodiment of this disclosure, the first conductive pattern 165 and the second conductive pattern 175 can contain, for example, metal. More specifically, the first conductive pattern 165 and the second conductive pattern 175 can each include aluminum (Al), titanium (Ti), molybdenum (Mo), calcium (Ca), barium (Ba), copper (Cu), etc. The first conductive pattern 165 and the second conductive pattern 175 can have reductive properties. For example, each of the first conductive pattern 165 and the second conductive pattern 175 can be a metal pattern made of metal such as aluminum (Al), titanium (Ti), molybdenum (Mo), calcium (Ca), barium (Ba), copper (Cu), or an alloy thereof. However, another embodiment of this disclosure is not limited thereto, and each of the first conductive pattern 165 and the second conductive pattern 175 may be made of transparent conductive oxide (TCO). The transparent conductive oxide (TCO) may include, for example, at least one of an IZO (InZnO)-based conductive material, an ITO (InSnO)-based conductive material, and a Fe-IZO (FeInZnO)-based conductive material. The transparent conductive oxide (TCO) may have a carrier concentration higher than that of the oxide semiconductor material, and may have a carrier concentration of, for example, 1×10²⁰/cm³ or higher.

The first conductive pattern 165 does not overlap with the first amorphous portion 130a.

The first conductive pattern 165 can be disposed on the first crystalline portion 130c in contact with the first crystalline portion 130c. During the doping process for the first active layer 130, the first conductive pattern 165 can block the dopant, so that the first crystalline portion 130c may not be amorphized and crystallinity can be maintained. For example, when the first conductive pattern 165 is a metal pattern made of metal, the first conductive pattern 165 effectively blocks the dopant, and thus the first crystalline portion 130c may not be amorphized and can maintain crystallinity. However, another embodiment of this disclosure is not limited thereto. For example, when the first conductive pattern 165 is made of transparent conductive oxide (TCO), the dopant may pass through the first conductive pattern 165, and as a result, the first crystalline portion 130c may be partially or entirely amorphized. In this case, a structure in which the first conductive pattern 165 overlaps an amorphous portion of the first active layer 130 can be obtained.

The second conductive pattern 175 does not overlap with the second amorphous portion 130b.

The second conductive pattern 175 can be disposed on the second crystalline portion 130d in contact with the second crystalline portion 130d. During the doping process for the first active layer 130, the second conductive pattern 175 can block the dopant, so that the second crystalline portion 130d may not be amorphized and crystallinity can be maintained. For example, when the second conductive pattern 175 is a metal pattern made of metal, the second conductive pattern 175 effectively blocks the dopant, and thus the second crystalline portion 130d may not be amorphized and can maintain crystallinity. However, another embodiment of this disclosure is not limited thereto. For example, when the second conductive pattern 175 is made of transparent conductive oxide (TCO), the dopant may pass through second conductive pattern 175, and as a result, the second crystalline portion 130d may be partially or entirely amorphized. In this case, a structure in which the second conductive pattern 175 overlaps an amorphous portion of the first active layer 130 can be obtained.

According to an embodiment of this disclosure, the first conductive pattern 165 can contact the source electrode 160, and the second conductive pattern 175 can contact the drain electrode 170.

Among the first active layer 130, the first crystalline portion 130c, which is spaced apart from the channel portion 130n and contacts the first conductive pattern 165, and the second crystalline portion 130d, which is spaced apart from the channel portion 130n and in contact with the second conductive pattern 175, can be reduced, respectively, to have excellent electrical conductivity.

Specifically, when a portion of the first active layer 130 in contact with the first conductive pattern 165 and the second conductive pattern 175 is reduced, oxygen defects occur in the contact portion, thereby improving electrical conductivity and resulting in the same effect as conductorization. As a result, a smooth electrical connection can be made between the source electrode 160 and the channel portion 130n and between the drain electrode 170 and the channel portion 130n. Also, the first conductive pattern 165 can have a same length as the first crystalline portion 130c, and the second conductive pattern 175 can have a same length as the second crystalline portion 130d, but embodiments are not limited thereto. Also, each of the first amorphous portion 130a and the second amorphous portion 130b can have a smaller length than each of the first conductive pattern 165, the second conductive pattern 175, the first crystalline portion 130c, the second conductive pattern 175 and the channel portion 130n, but embodiments are not limited thereto. Also, both of the first conductive pattern 165 and the second conductive pattern 175 can be thinner than the first active layer 130, but embodiments are not limited thereto.

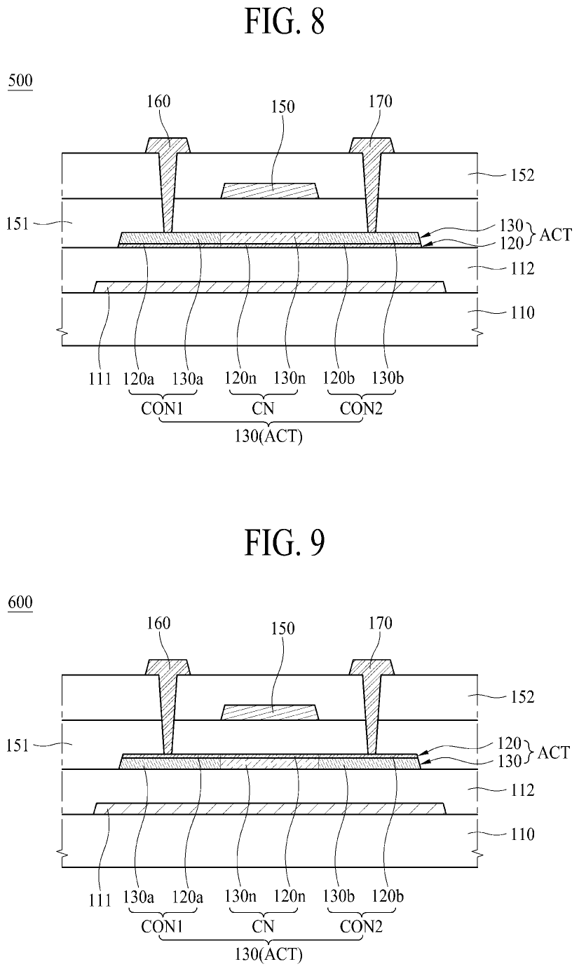

FIG. 8 is a cross-sectional view of a thin film transistor 500 according to another embodiment of the present disclosure.

Referring to FIG. 8, the active layer ACT can include a first active layer 130 and an amorphous active layer 120. The amorphous active layer 120 can overlap the first active layer 130 to contact the first active layer 130. The amorphous active layer 120 has an amorphous structure. The amorphous active layer 120 and the first active layer 130 can have a vertically stacked structure. Also, the amorphous active layer 120 can be thinner than the first active layer 130, but embodiments are not limited thereto.

Referring to FIG. 8, the amorphous active layer 120 can include a channel portion 120n overlapping with the gate electrode 150, a first connection portion 120a connected to one side of the channel portion 120n, and a second connection portion 120b connected to the other side of the channel portion 120n. The channel portion 120n, the first connection portion 120a, and the second connection portion 120b of the amorphous active layer 120 can have an amorphous structure. In the embodiments of the present disclosure, the channel portion can be referred to as “channel,” and the channel portion 120n may be referred to as “channel 120n.”

The channel portion CN of the active layer ACT can be formed by the channel portion 130n of the first active layer 130 and the channel portion 120n of the amorphous active layer 120. Also, the channel portion 130n of the first active layer 130 can have a same length as the channel portion 120n of the amorphous active layer 120, but embodiments are not limited thereto.

The first connection portion CON1 of the active layer ACT can be formed by the first amorphous portion 130a of the first active layer 130 and the first connection portion 120a of the amorphous active layer 120. In addition, the second amorphous portion 130b of the first active layer 130 and the second connection portion 120b of the amorphous active layer 120 can form the second connection portion CON2 of the active layer ACT.

The channel portion 120n of the amorphous active layer 120 can have a carrier concentration lower than a carrier concentration of the channel portion 130n of the first active layer 130. The amorphous active layer 120 can be made of an oxide semiconductor material having excellent stability and excellent patterning properties instead of having a low carrier concentration.

Instead of having a low carrier concentration, the amorphous active layer 120 with excellent stability and excellent patterning properties can serve as a blocking layer to block hydrogen diffusion, and has excellent process properties to secure process margins.

In addition, the amorphous active layer 120 can serve as a seed layer for stably crystallizing the first active layer 130. As a result, the channel portion 130n of the first active layer 130 can have uniform crystallinity and maintain high mobility characteristics, and the thin film transistor 500 can have excellent reliability and high mobility characteristics.

According to another embodiment of the present disclosure, the amorphous active layer 120 can have a thickness of 1 nm to 5 nm (e.g., 3 nm).

When the thickness of the amorphous active layer 120 is less than 1 nm, hydrogen blocking characteristics by the amorphous active layer 120 can be degraded, process properties can be degraded, and the amorphous active layer 120 may not function as a seed layer, thereby not stably crystallizing the first active layer 130.

On the other hand, when the thickness of the amorphous active layer 120 exceeds 5 nm, irregular crystals can be generated in the amorphous active layer 120 and irregularities can occur on the surface, resulting in degraded planarization properties. As a result, it may not sufficiently function as a seed layer to stably crystallize the first active layer 130. For example, a thickness of 1 nm to 5 nm (e.g., 3 nm) for the amorphous active layer 120 can effectively balance these considerations.

According to another embodiment of this disclosure, the amorphous active layer 120 can have a thickness of 1.5 nm to 3.5 nm (e.g., 2.5 nm) to have an excellent hydrogen blocking property, excellent process properties, and serve as an excellent seed layer.

Referring to FIG. 8, the first active layer 130 can be disposed between the amorphous active layer 120 and the gate electrode 150. Specifically, the amorphous active layer 120 can be disposed below the first active layer 130. According to another embodiment of the present disclosure, a space between the first active layer 130 and the substrate 110 is referred to as a lower portion of the first active layer 130.

FIG. 9 is a cross-sectional view of a thin film transistor 600 according to another embodiment of the present disclosure. Referring to FIG. 9, the amorphous active layer 120 can be disposed to contact the gate insulating layer 151. The amorphous active layer 120 can be disposed between the first active layer 130 and the gate insulating layer 151 and serve as an interface layer improving physical or chemical surface characteristics between the first active layer 130 and the gate insulating layer 151.

In the thin film transistor 600 according to FIG. 9, the amorphous active layer 120 can be disposed between the first active layer 130 and the gate electrode 150. Specifically, the amorphous active layer 120 can be disposed on the first active layer 130. According to another embodiment of the present disclosure, the direction opposite to the substrate 110 is referred to as an upper portion of the first active layer 130. According to another embodiment of the present disclosure, the channel portion 130n of the first active layer 130 has a crystalline structure. On the other hand, the gate insulating layer 151 may generally have an amorphous structure. When the channel portion 130n of the first active layer 130 having a crystalline structure is in direct contact with the amorphous active layer 120 having an amorphous structure, the channel portion 130n of the first active layer 130 and the amorphous active layer 120 may not have excellent adhesion or excellent bonding strength, and problems such as carrier traps may occur at the interface due to increased disorders at the interface. According to another embodiment of the present disclosure, the amorphous active layer 120 is disposed between the gate insulating layer 151 and the first active layer 130, and contacts both the gate insulating layer 151 and the first active layer 130. Since the amorphous active layer 120 has an amorphous structure similar to that of the gate insulating layer 151, the amorphous active layer 120 can have excellent compatibility with the gate insulating layer 151. In addition, since the amorphous active layer 120 is made of an oxide semiconductor material, the amorphous active layer 120 can have excellent compatibility with the first active layer 130, which is made of an oxide semiconductor material. As such, the amorphous active layer 120 having excellent compatibility with the gate insulating layer 151 and having excellent compatibility with the first active layer 130 is disposed between the gate insulating layer 151 and the first active layer 130, the amorphous active layer 120 can improve interface characteristics between the gate insulating layer 151 and the first active layer 130. In addition, as the amorphous active layer 120 is disposed between the gate insulating film 151 and the first active layer 130, disorder of bonding at the interface between the gate insulating film 151 and the gate insulating film 151 is reduced, thereby the influence of hydrogen is suppressed and irregularity dispersion of devices can be reduced. In addition, since the disorder of bonding at the interface is reduced, defects of the device are reduced, and as a result, the reliability of the device (thin film transistor) can be improved.

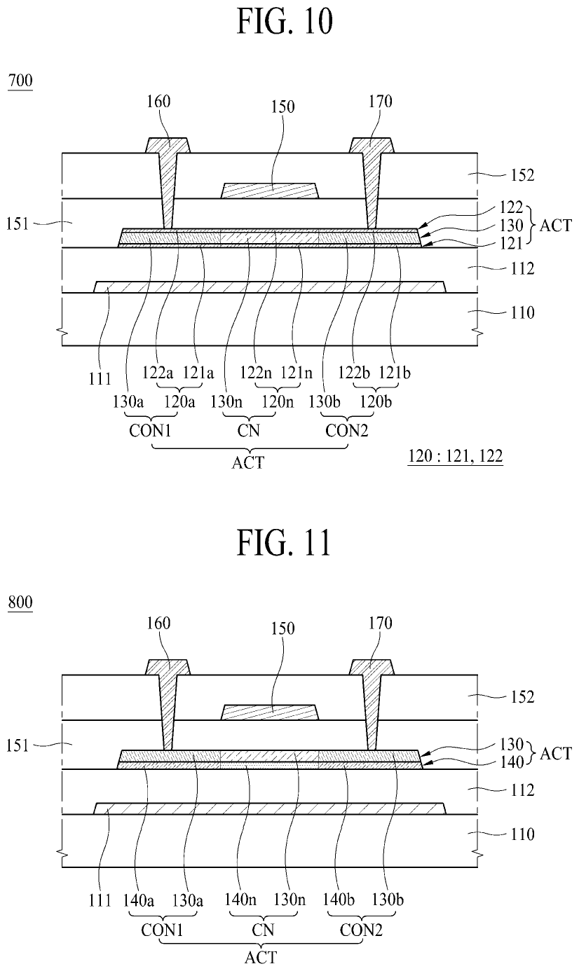

FIG. 10 is a cross-sectional view of a thin film transistor 700 according to another embodiment of the present disclosure.

Referring to FIG. 10, an amorphous active layer 120 can be disposed above and below the first active layer 130. Specifically, the amorphous active layer 120 includes the first amorphous active layer 121 in contact with the first active layer 130 and a second amorphous active layer 122 opposite to the first amorphous active layer 121 and in contact with the first active layer 130. For example, the active layer ACT can have a triple layer structure including the first active layer 130 disposed between the first amorphous active layer 121 and the second amorphous active layer 122. Also, both of the first amorphous active layer 121 and the second amorphous active layer 122 can be thinner than the first active layer 130, but embodiments are not limited thereto.

The first amorphous active layer 121 disposed below the first active layer 130 can be referred to as a lower amorphous active layer, and the second amorphous active layer 122 disposed above the first active layer 130 can be referred to as an upper amorphous active layer.

The first amorphous active layer 121 can include a channel portion 121n, a first connection portion 121a, and a second connection portion 121b. The channel portion 121n, the first connection portion 121a, and the second connection portion 121b of the first amorphous active layer 121 can all have an amorphous structure.

The second amorphous active layer 122 can include a channel portion 122n, a first connection portion 122a, and a second connection portion 122b. The channel portion 122n, the first connection portion 122a, and the second connection portion 122b of the second amorphous active layer 122 can all have an amorphous structure.

The channel portion CN of the active layer ACT can be formed by the channel portion 130n of the first active layer 130, the channel portion 121n of the first amorphous active layer 121, and the channel portion 122n of the second amorphous active layer 122. For example, the channel portion CN of the active layer ACT can have a triple layer structure.

The first connection portion CON1 of the active layer ACT can be formed by the first amorphous portion 130a of the first active layer 130, the first connection portion 121a of the first amorphous active layer 121 and the first connection portion 122a of the second amorphous active layer 122.

In addition, the second connection portion CON2 of the active layer ACT can be formed by the second amorphous portion 130b of the first active layer 130, the second connection portion 121b of the first amorphous active layer 121, and the second connection portion 122b of the second amorphous active layer 122.

FIG. 11 is a cross-sectional view of a thin film transistor 800 according to another embodiment of the present disclosure.

The active layer ACT of the thin film transistor 800 according to another embodiment of the present disclosure can include a first active layer 130 and a barrier active layer 140. The barrier active layer 140 can overlap with the first active layer 130 to contact the first active layer 130. The barrier active layer 140 and the first active layer 130 can be vertically stacked on top of each other. Also, a length of the barrier active layer 140 can be equal to a length of the first active layer 130, but embodiments are not limited thereto.

The barrier active layer 140 can include a channel portion 140n overlapping with the gate electrode 150, a first amorphous portion 140a connected to one side of the channel portion 140n, and a second amorphous portion 140b connected to the other side of the channel portion 140n. Also, the barrier active layer 140 can be thinner than the first active layer 130.

The channel portion 140n of the barrier active layer 140 has a crystalline structure. The first amorphous portion 140a and the second amorphous portion 140b of the barrier active layer 140 can have an amorphous structure.

The channel portion CN of the active layer ACT can be formed by the channel portion 130n of the first active layer 130 and the channel portion 140n of the barrier active layer 140.

The first connection portion CON1 of the active layer ACT can be formed by the first amorphous portion 130a of the first active layer 130 and the first amorphous portion 140a of the barrier active layer 140. In addition, the second connection portion CON2 of the active layer ACT can be formed by the second amorphous portion 130b of the first active layer 130 and the second amorphous portion 140b of the barrier active layer 140.

The channel portion 140n of the barrier active layer 140 can have a carrier concentration lower than a carrier concentration of the channel portion 130n of the first active layer 130. The barrier active layer 140 can be made of an oxide semiconductor material having excellent stability instead of having a low carrier concentration.

More specifically, the barrier active layer 140 can be made of an oxide semiconductor material having excellent stability and crystallinity. According to another embodiment of the present disclosure, the barrier active layer 140 can be made of a gallium (Ga)-based oxide semiconductor material. When the barrier active layer 140 includes gallium (Ga) and indium (In), the content (at %) of gallium (Ga) can be greater than the content (at %) of indium (In) based on the number of atoms.

According to another embodiment of this disclosure, the barrier active layer 140 can be formed of a crystalline oxide semiconductor material, and the first amorphous portion 140a and the second amorphous portion 140b can be formed by dopant doping injecting dopant ions into a specific region. The first amorphous portion 140a and the second amorphous portion 140b of the barrier active layer 140 can include a dopant doped by ion implantation or ion injection. The dopant can include at least one of boron (B), phosphorus (P), fluorine (F), and hydrogen (H).

Referring to FIG. 11, doping can be performed using the gate electrode 150 as a mask, and as a result, a portion of the barrier active layer 140 overlapping the gate electrode 150 may not be doped to become a channel portion 140n. By doping by dopant, the boundary of the channel portion 130n can be clarified. Also, the channel portion 140n can have a same length as the gate electrode 150 and the channel portion 130n.

The barrier active layer 140 with excellent stability and crystallinity can serve as a blocking layer to block hydrogen diffusion and a seed layer to stably crystallize the first active layer 130 (e.g., barrier active layer 140 can provide dual functions of blocking hydrogen and seeding crystallization). As a result, the channel portion 130n of the first active layer 130 can have uniform crystallinity and maintain high mobility characteristics, and the thin film transistor 800 can have excellent reliability and high mobility characteristics.

According to another embodiment of the present disclosure, the barrier active layer 140 can have a thickness of 5 to 30 nm (e.g., 17.5 nm).

If the thickness of the barrier active layer 140 is less than 5 nm, the hydrogen blocking characteristics by the barrier active layer 140 can be degraded, and the barrier active layer 140 may not fully function as the seed layer.

On the other hand, if the thickness of the barrier active layer 140 exceeds 30 nm, the thickness of the active layer ACT may be thicker than necessary, which can degrade the process properties or patterning properties of the active layer ACT and can be disadvantageous in thinning the device and increasing the weight of the device.

According to another embodiment of this disclosure, to ensure excellent hydrogen blocking properties and crystallinity, the barrier active layer 140 can have a thickness of 5 nm to 30 nm, more specifically 5 nm to 25 nm, and 10 nm to 15 nm (e.g., 12.5 nm), in order to effectively balance the above considerations.

Referring to FIG. 11, the first active layer 130 can be disposed between the barrier active layer 140 and the gate electrode 150. Specifically, the barrier active layer 140 can be disposed under the first active layer 130. According to another embodiment of the present disclosure, a space between the first active layer 130 and the substrate 110 is referred to as a lower portion of the first active layer 130.

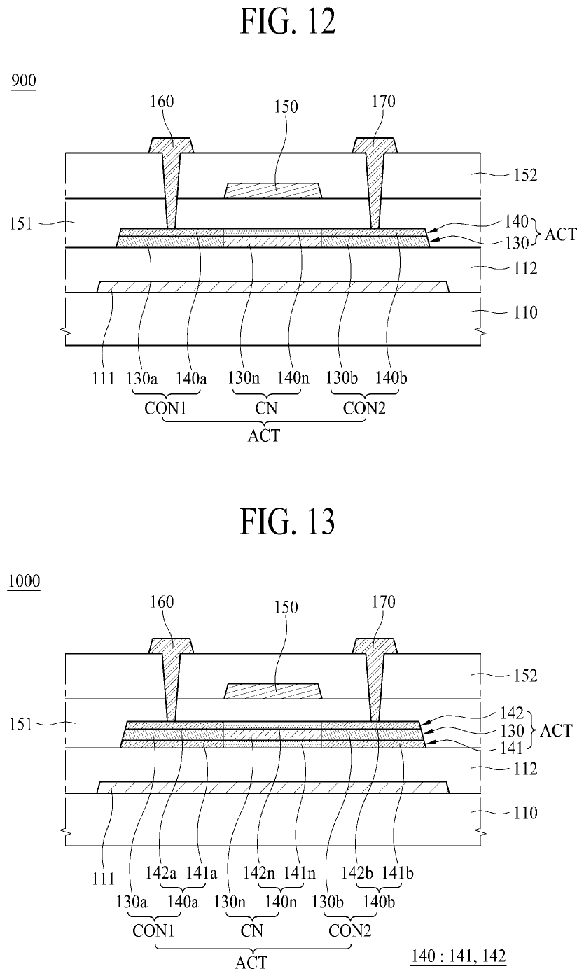

FIG. 12 is a cross-sectional view of a thin film transistor 900 according to another embodiment of the present disclosure.

In the thin film transistor 900 according to FIG. 12, the barrier active layer 140 can be disposed between the first active layer 130 and the gate electrode 150. Specifically, the barrier active layer 140 can be disposed on the first active layer 130. According to another embodiment of the present disclosure, the direction opposite to the substrate 110 is referred to as an upper portion of the first active layer 130.

FIG. 13 is a cross-sectional view of a thin film transistor 1000 according to another embodiment of the present disclosure.

Referring to FIG. 13, a barrier active layer 140 can be disposed above and below the first active layer 130. Specifically, the barrier active layer 140 can include a first barrier active layer 141 in contact with the first active layer 130 and a second barrier active layer 142 in contact with the first active layer 130 opposite to the first barrier active layer 141 (e.g., a triple layer structure).

The first barrier active layer 141 disposed below the first active layer 130 can be referred to as a lower barrier active layer, and the second barrier active layer 142 disposed above the first active layer 130 can be referred to as an upper barrier active layer.

The first barrier active layer 141 can include a channel portion 141n, a first amorphous portion 141a, and a second amorphous portion 141b. The channel portion 141n of the first barrier active layer 141 can have a crystalline structure, and the first amorphous portion 141a and the second amorphous portion 141b can have an amorphous structure.

The second barrier active layer 142 can include a channel portion 142n, a first amorphous portion 142a, and a second amorphous portion 142b. The channel portion 142n of the second barrier active layer 142 can have a crystalline structure, and the first amorphous portion 142a and the second amorphous portion 142b can have an amorphous structure.

The channel portion CN of the active layer ACT can be formed by the channel portion 130n of the first active layer 130, the channel portion 141n of the first barrier active layer 141, and the channel portion 142n of the second barrier active layer 142.

The first amorphous portion 130a of the first active layer 130, the first amorphous portion 141a of the first barrier active layer 141, and the first amorphous portion 142a of second barrier active layer 142 can form the first connection portion CON1 of the active layer ACT.

In addition, the second amorphous portion 130b of the first active layer 130, the second amorphous portion 141b of the first barrier active layer 141, and the second amorphous portion 142b of the second barrier active layer 142 can form the second connection portion CON2 of the active layer ACT. Also, both of the first barrier active layer 141 and the second barrier active layer 142 can be thinner than the first active layer 130. Also, each of the first barrier active layer 141, the second barrier active layer 142 and the first active layer 130 can have thicknesses that are different from each other.

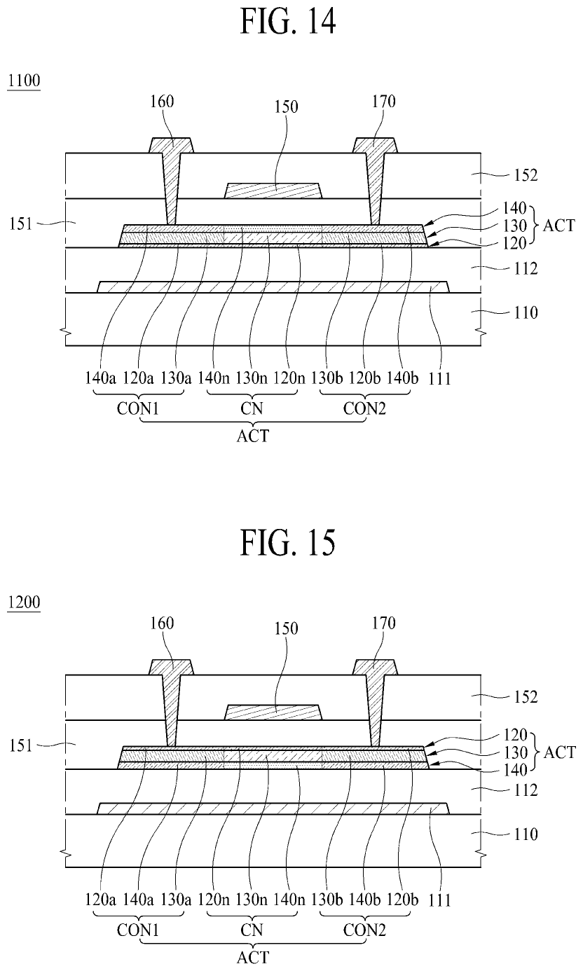

FIG. 14 is a cross-sectional view of a thin film transistor 1100 according to another embodiment of the present disclosure.

Referring to FIG. 14, the active layer ACT of the thin film transistor 1100 can include a first active layer 130, an amorphous active layer 120, and a barrier active layer 140. The amorphous active layer 120 and the barrier active layer 140 can be disposed to be oriented around the first active layer 130, and can contact the first active layer 130, respectively.

FIG. 14 exemplarily illustrates a structure in which an amorphous active layer 120 is placed under the first active layer 130 and a barrier active layer 140 is placed above the first active layer 130. Specifically, the amorphous active layer 120 can be disposed between the substrate 110 and the first active layer 130, and the first active layer 130 can be disposed between the amorphous active layer 120 and the barrier active layer 140.

The channel portion CN of the active layer ACT can be formed by the channel portion 130n of the first active layer 130, the channel portion 120n of the amorphous active layer 120, and the channel portion 140n of the barrier active layer 140.

The first connection portion CON1 of the active layer ACT can be formed by the first amorphous portion 130a of the first active layer 130, the first connection portion 120a of the amorphous active layer 120, and the first amorphous portion 140a of the barrier active layer 140.

In addition, the second connection portion CON2 of the active layer ACT can be formed by the second amorphous portion 130b of the first active layer 130, the second connection portion 120b of the amorphous active layer 120, and the second amorphous portion 140b of the barrier active layer 140. Also, each of the barrier active layer 140, the first active layer 130 and the amorphous active layer 120 can have thicknesses that are different from each other.

FIG. 15 is a cross-sectional view of a thin film transistor 1200 according to another embodiment of the present disclosure.

FIG. 15 discloses an example structure in which an amorphous active layer 120 is disposed above the first active layer 130 and a barrier active layer 140 is disposed under the first active layer 130. Specifically, a barrier active layer 140 can be disposed between the substrate 110 and the first active layer 130, and a first active layer 130 can be disposed between the amorphous active layer 120 and the barrier active layer 140.

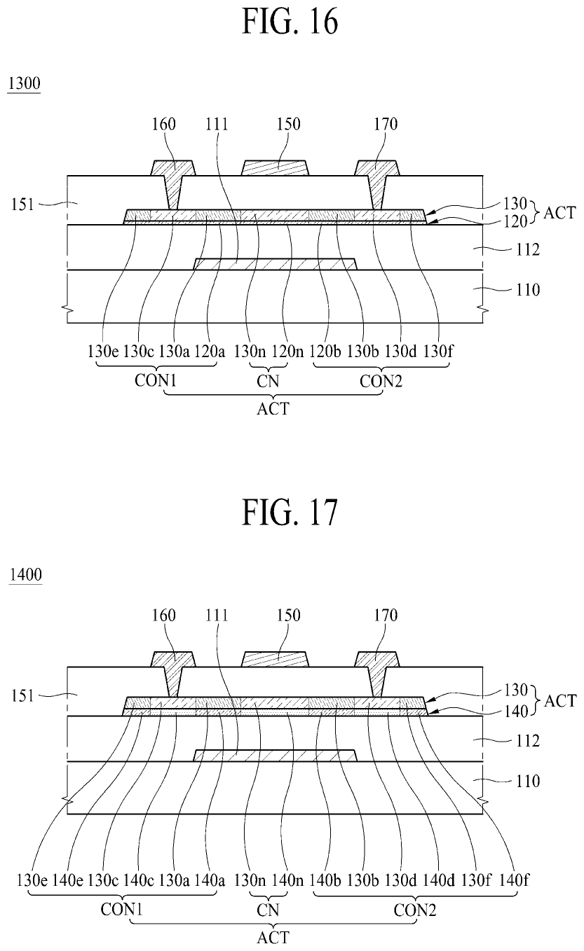

FIG. 16 is a cross-sectional view of a thin film transistor 1300 according to another embodiment of the present disclosure.

The thin film transistor 1300 of FIG. 16 has a structure in which an amorphous active layer 120 is placed under the first active layer 130 of the thin film transistor 200 shown in FIG. 5.

Referring to FIG. 16, the channel portion CN of the active layer ACT can be formed by the channel portion 130n of the first active layer 130 and the channel portion 120n of the amorphous active layer 120.

The first connection portion CON1 of the active layer ACT can be formed by the first amorphous portion 130a, the first crystalline portion 130c, and the third amorphous portion 130e of the first active layer 130, and the first connection portion 120a of the amorphous active layer 120.

In addition, the second connection portion CON2 of the active layer ACT can be formed by the second amorphous portion 130b, the second crystalline portion 130d, and the fourth amorphous portion 130f of the first active layer 130, and the second connection portion 120b of the amorphous active layer 120.

FIG. 16 discloses a thin film transistor 1300 having a structure in which an amorphous active layer 120 is disposed below the first active layer 130, but embodiments of the present disclosure are not limited thereto. An amorphous active layer 120 can be disposed above the first active layer 130, or an amorphous active layer 120 can be disposed on both upper and lower surfaces of the first active layer 130 (e.g., a triple layer structure).

FIG. 17 is a cross-sectional view of a thin film transistor 1400 according to another embodiment of the present disclosure.

The thin film transistor 1400 of FIG. 17 has a structure in which a barrier active layer 140 is placed under the first active layer 130 of the thin film transistor 200 shown in FIG. 5.

Referring to FIG. 17, the barrier active layer 140 can further include a first crystalline portion 140c in contact with the first amorphous portion 140a. The first amorphous portion 140a of the barrier active layer 140 can be disposed between the channel portion 140n and the first crystalline portion 140c.

In addition, the barrier active layer 140 can further include a second crystalline portion 140d in contact with the second amorphous portion 140b. The second amorphous portion 140b of the barrier active layer 140 can be disposed between the channel portion 140n and the second crystalline portion 140d.

According to another embodiment of this disclosure, the first crystalline portion 140c and the second crystalline portion 140d of the barrier active layer 140 can have the same crystal structure as the channel portion 140n.

The first crystalline portion 140c of the barrier active layer 140 can overlap with the source electrode 160, and the second crystalline portion 140d can overlap with the drain electrode 170. However, embodiments of this disclosure are not limited to this, and the first crystalline portion 140c can overlap with the drain electrode 170, and the second crystalline portion 140d can overlap with the source electrode 160. The barrier active layer 140 can further include a third amorphous portion 140e in contact with the first crystalline portion 140c. The first crystalline portion 140c can be disposed between the first amorphous portion 140a and the third amorphous portion 140e. The third amorphous portion 140e of the barrier active layer 140 does not overlap with the gate electrode 150, the source electrode 160, and the drain electrode 170.

In addition, the barrier active layer 140 can further include a fourth amorphous portion 140f in contact with the second crystalline portion 140d. The second crystalline portion 140d of the barrier active layer 140 can be disposed between the second amorphous portion 140b and the fourth amorphous portion 140f. The fourth amorphous portion 140f of the barrier active layer 140 does not overlap with the gate electrode 150, the source electrode 160, and the drain electrode 170.

Referring to FIG. 17, the first connection portion CON1 can include a first amorphous portion 130a, a first crystalline portion 130c, and a third amorphous portion 130e of the first active layer 130, and a first amorphous portion 140a, a first crystalline portion 140c, and a third amorphous portion 140e of the barrier active layer 140.

The second connection portion CON2 can include a second amorphous portion 130b, a second crystalline portion 130d, and a fourth amorphous portion 130f of the first active layer 130, and a second amorphous portion 140b, a second crystalline portion 140d, and a fourth amorphous portion 140f of the barrier active layer 140.

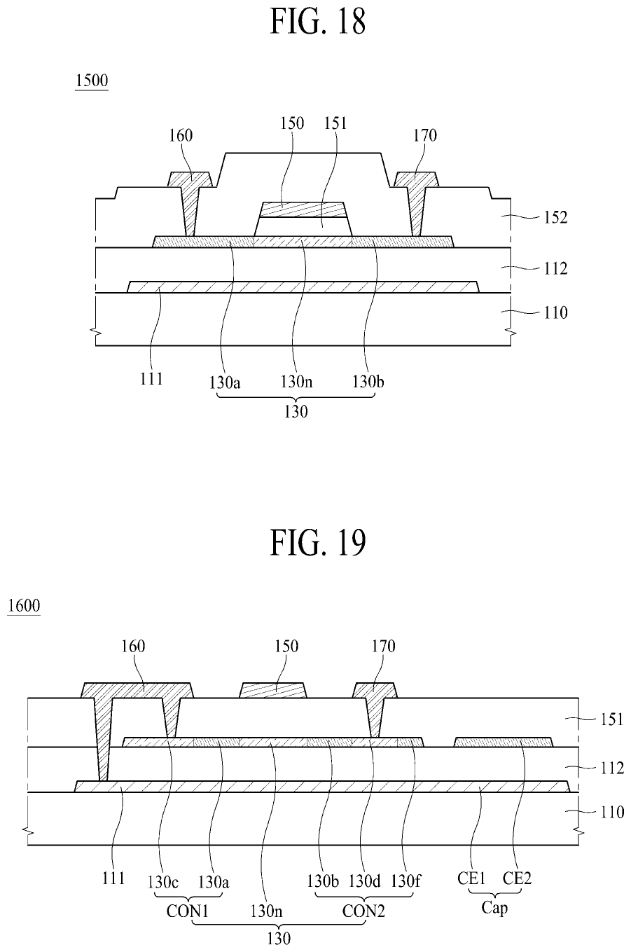

FIG. 18 is a cross-sectional view of a thin film transistor 1500 according to another embodiment of the present disclosure.

Referring to FIG. 18, a gate insulating layer 151 is patterned. For example, the gate insulating layer 151 can be patterned in a shape corresponding to the gate electrode 150. For example, the gate insulating layer 151 can have a length that is equal to or approximately equal to a length of the gate electrode 150, but embodiments are not limited thereto. Also, the light blocking layer can have a length that is greater than a length of the first active layer 130, but embodiments are not limited thereto.

FIG. 19 is a cross-sectional view of a thin film transistor substrate 1600 according to another embodiment of the present disclosure.

The thin film transistor according to FIG. 19 can be connected to a capacitor Cap. As shown in FIG. 19, a configuration including a substrate (base substrate) 110, a thin film transistor, and a capacitor Cap is also referred to as a “thin film transistor substrate.”

According to another embodiment of this disclosure, the thin film transistor substrate 1600 can further include a light blocking layer 111 connected to either the source electrode 160 or the drain electrode 170 and a capacitor Cap connected to the light blocking layer 111.

FIG. 19 discloses a structure in which the light blocking layer 111 is connected to the source electrode 160. However, another embodiment of the present disclosure is not limited thereto, and the light blocking layer 111 can be connected to the drain electrode 170.

The capacitor Cap includes a first capacitor electrode CE1 and a second capacitor electrode CE2. According to another embodiment of the present disclosure, the first capacitor electrode CE1 can be connected to the light blocking layer 111. Referring to FIG. 19, a portion of the light blocking layer 111 can be a first capacitor electrode CE1. The first capacitor electrode CE1 can be integrally formed with the light blocking layer 111.

As the first capacitor electrode CE1 is connected to the light blocking layer 111, the same voltage as that applied to the source electrode 160 can be applied to the first capacitor electrode CE1.

The second capacitor electrode CE2 can be disposed on the same layer as the first active layer 130 constituting the active layer ACT and can be made of the same material. In addition, the second capacitor electrode CE2 has an amorphous structure and can have the same composition as the first amorphous portion 130a of the first active layer 130. Also, light blocking layer 111 can have a length that is longer than a sum of a length of the first active layer 130 and a length of the second capacitor electrode CE2, but embodiments are not limited thereto.

The second capacitor electrode CE2 can be patterned together with the first active layer 130 and then doped with a dopant.

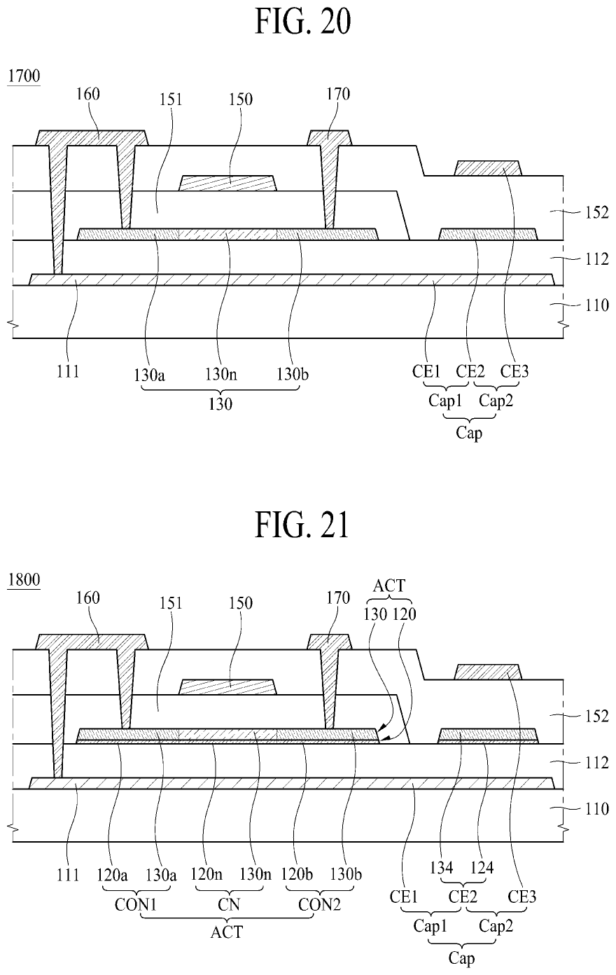

FIG. 20 is a cross-sectional view of a thin film transistor substrate 1700 according to another embodiment of the present disclosure.

In FIG. 20, a thin film transistor is connected to a capacitor Cap.

The capacitor Cap of FIG. 20 includes a first capacitor electrode CE1, a second capacitor electrode CE2, and a third capacitor electrode CE3. The first capacitor electrode CE1 can be connected to the light blocking layer 111. Referring to FIG. 20, a portion of the light blocking layer 111 can be a first capacitor electrode CE1. The first capacitor electrode CE1 can be integrally formed with the light blocking layer 111.

Since the light blocking layer 111 is connected to the source electrode 160, the same voltage that is applied to the source electrode 160 can be applied to the first capacitor electrode CE1.

Referring to FIG. 20, the second capacitor electrode CE2 is disposed on the same layer as the first active layer 130 constituting the active layer ACT, and can be made of the same material and during a same process. The second capacitor electrode CE2 can be doped during a selective doping process for the first active layer 130. As a result, the second capacitor electrode CE2 can have an amorphous structure or include a layer having an amorphous structure.

The capacitor Cap of FIG. 20 includes a third capacitor electrode CE3 on the second capacitor electrode CE2. The third capacitor electrode CE3 can be disposed on the same layer as the source electrode 160 and the drain electrode 170, and can be made of the same material as the source electrode 160 and the drain electrode 170 and through a same processing step. For example, when the source electrode 160 and the drain electrode 170 are formed, a third capacitor electrode CE3 can also be formed at the same time.

The first capacitor Cap1 can be formed by overlapping the first capacitor electrode CE1 with the second capacitor electrode CE2. In addition, the second capacitor Cap2 can be formed by overlapping the second capacitor electrode CE2 and the third capacitor electrode CE3.

The capacitor Cap includes a first capacitor Cap1 and a second capacitor Cap2.

FIG. 21 is a cross-sectional view of a thin film transistor substrate 1800 according to another embodiment of the present disclosure.

The thin film transistor substrate 1800 of FIG. 21 further includes an amorphous active layer 120 compared to the thin film transistor substrate 1700 of FIG. 20. The thin film transistor contained in the thin film transistor substrate 1800 of FIG. 21 has substantially the same configuration as the thin film transistor 500 of FIG. 8, except that the source electrode 160 is connected to the light blocking layer 111.

The active layer ACT of the thin film transistor substrate 1800 illustrated in FIG. 21 can include a first active layer 130 and an amorphous active layer 120. The amorphous active layer 120 and the first active layer 130 can have a vertically stacked structure.

Referring to FIG. 21, the second capacitor electrode CE2 can include a first layer 124 made of an amorphous oxide semiconductor material and a second layer 134 made of the same oxide semiconductor material as the first active layer 130. The first layer 124 of the second capacitor electrode CE2 and the amorphous active layer 120 can be made of the same oxide semiconductor material.

FIG. 21 illustrates the configuration in which the amorphous active layer 120 is disposed under the first active layer 130, but another embodiment of this disclosure is not limited thereto. Instead of the amorphous active layer 120, the barrier active layer 140 can be applied. In addition, the amorphous active layer 120 or barrier active layer 140 can be placed above the first active layer 130, as well as under the first active layer 130.

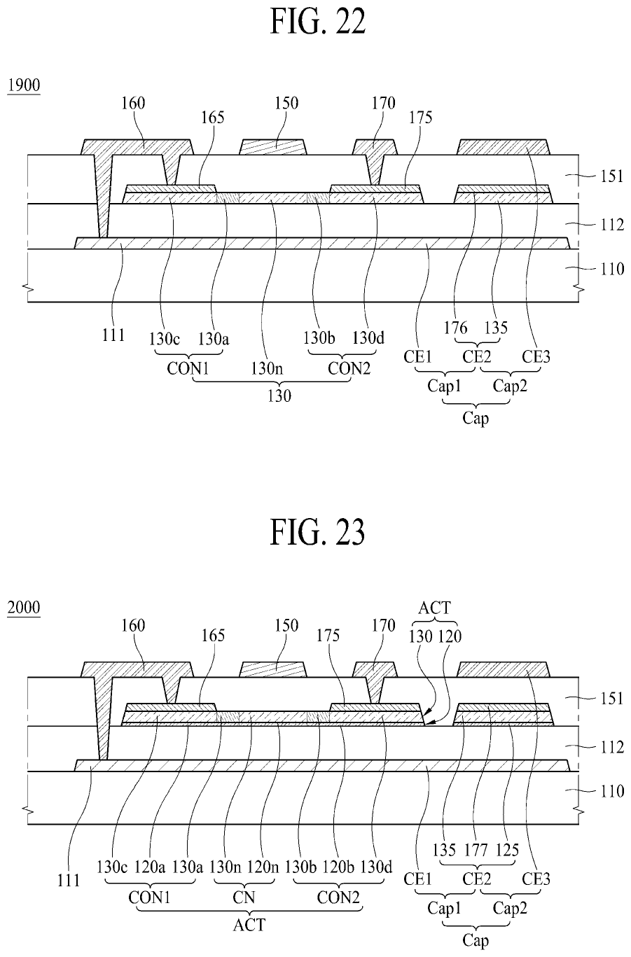

FIG. 22 is a cross-sectional view of a thin film transistor substrate 1900 according to another embodiment of the present disclosure.

The thin film transistor substrate 1900 of FIG. 22 includes a thin film transistor and a capacitor Cap. The thin film transistor contained in the thin film transistor substrate 1900 of FIG. 22 has substantially the same configuration as the thin film transistor 400 of FIG. 7, except that the source electrode 160 is connected to the light blocking layer 111.

The capacitor Cap includes a first capacitor electrode CE1 and a second capacitor electrode CE2. The first capacitor electrode CE1 can be connected to the light blocking layer 111. Referring to FIG. 22, a portion of the light blocking layer 111 can be a first capacitor electrode CE1. The first capacitor electrode CE1 can be integrally formed with the light blocking layer 111.

Since the light blocking layer 111 is connected to the source electrode 160, the same voltage that is applied to the source electrode 160 can also be applied to the first capacitor electrode CE1.

Referring to FIG. 22, the second capacitor electrode CE2 can include a first layer 135 and a second layer 176. The first layer 135 is protected by a second layer 176 made of the same material as the conductive patterns 165 and 175. As a result, the first layer 135 can have a crystalline structure. According to another embodiment of the present disclosure, the second layer 176 can be referred to as a conductive pattern. For example, second layer 176 can have a higher conductivity than the first layer 135. Also, the second layer 176 can be thinner than the first layer 135, but embodiments are not limited thereto. For example, the second layer 176 can be thicker than the first layer 135, or the second layer 176 and the first layer 135 can have the same thickness.

More specifically, the first layer 135 of the second capacitor electrode CE2 illustrated in FIG. 22 can be disposed on the same layer as the first active layer 130. The first layer 135 of the second capacitor electrode CE2 has a crystalline structure or includes a layer having a crystalline structure, and can have the same composition as the channel portion 130n and the first crystalline portion 130c of the first active layer 130.

The second layer 176 of the second capacitor electrode CE2 can be disposed on the same layer as the first conductive pattern 165 and the second conductive pattern 175. The second layer 176 of the second capacitor electrode CE2 can be made of the same material as the first conductive pattern 165 and the second conductive pattern 175. In the patterning process of the first conductive pattern 165 and the second conductive pattern 175, the second layer 176 of the second capacitor electrode CE2 can be patterned together.

FIG. 23 is a cross-sectional view of a thin film transistor substrate 2000 according to another embodiment of the present disclosure.

Compared to the thin film transistor substrate 1900 of FIG. 22, the thin film transistor substrate 2000 of FIG. 23 further includes an amorphous active layer 120. The thin film transistor contained in the thin film transistor substrate 2000 of FIG. 23 is substantially the same as the thin film transistor 400 of FIG. 7 except including an amorphous active layer 120 and that the source electrode 160 is connected to the light blocking layer 111.

The active layer ACT of the thin film transistor substrate 2000 illustrated in FIG. 23 can include a first active layer 130 and an amorphous active layer 120. The amorphous active layer 120 and the first active layer 130 can have a vertically stacked structure.

Referring to FIG. 23, the second capacitor electrode CE2 can include a first layer 125 made of an amorphous oxide semiconductor material, a second layer 135 made of the same oxide semiconductor material as the first active layer 130, and a third layer 177 made of the same material as the conductive patterns 165, 175 (e.g., a triple layer structure). According to another embodiment of the present disclosure, the third layer 177 can be referred to as a conductive pattern.

FIG. 23 illustrates the configuration in which the amorphous active layer 120 is disposed under the first active layer 130, but embodiments of this disclosure are not limited thereto. Instead of the amorphous active layer 120, the barrier active layer 140 can be applied. In addition, the amorphous active layer 120 or the barrier active layer 140 can be disposed above the first active layer 130.

Hereinafter, a method of manufacturing a thin film transistor according to an embodiment of the present disclosure will be described.

According to an embodiment of the present disclosure, in order to manufacture a thin film transistor, an active layer ACT is formed on the substrate 110.

More specifically, referring to FIG. 1, a light blocking layer 111 can be formed on the substrate 110, a buffer layer 112 can be formed on the light blocking layer 111, and an active layer ACT can be formed on the buffer layer 112.

The active layer ACT can include a first active layer 130. In addition to the first active layer 130, the active layer ACT can also include at least one of the amorphous active layer 120 and the barrier active layer 140.

Forming the active layer ACT can include forming the first oxide semiconductor material layer using a crystalline oxide semiconductor material, patterning the first oxide semiconductor material layer to form an active pattern, and forming a first active layer having a crystalline active pattern by heat-treating the active pattern.

The first oxide semiconductor material layer can include an oxide semiconductor material and a crystallization control element. The crystallization control element can include at least one of beryllium (Be), boron (B), carbon (C), aluminum (Al), silicon (Si), iron (Fe), calcium (Ca), titanium (Ti), tantalum (Ta), vanadium (V), yttrium (Y), zirconium (Zr), hafnium (Hf), lanthanum (La), and germanium (G). More specifically, the hardening control element can include aluminum (Al).

In addition, the forming the active layer ACT can further include forming an amorphous oxide semiconductor material layer using an amorphous oxide semiconductor material.

In addition, the forming the active layer ACT can further include forming a barrier oxide semiconductor material layer using a crystalline oxide semiconductor material.

Next, a gate insulating layer 151 is formed on the active layer ACT. Contact holes can be formed in the gate insulating layer 151.

Then, the gate electrode 150 is formed on the gate insulating layer 151. The gate electrode 150 at least partially overlaps with the active layer ACT. Specifically, the gate electrode 150 is formed so that the gate electrode overlaps with the channel portion CN.

According to an embodiment of this disclosure, in the forming of the gate electrode 150, the source electrode 160 and the drain electrode 170 can be formed together with the gate electrode 150.

Next, the active layer ACT is selectively doped using a dopant.

In the doping of the dopant, the gate electrode 150 can serve as a mask for blocking the dopant. In addition, when the source electrode 160 and the drain electrode 170 are formed together with the gate electrode 150 in the forming of the gate electrode 150, the source electrode 160 and the drain electrode 170 can also serve as masks to block the dopant.

According to an embodiment of the present disclosure, a region of the active layer ACT doped with a dopant can have an amorphous structure. A region of the active layer ACT that is not doped with a dopant due to the blocking of the dopant can have a crystalline structure.

The dopant can include at least one of boron (B), phosphorus (P), fluorine (F), and hydrogen (H).

In addition, the first conductive pattern 165 and the second conductive pattern 175 can be formed on the active layer ACT. The first conductive pattern 165 and the second conductive pattern 175 are formed not to overlap with the gate electrode 150.

In the doping the active layer ACT with a dopant, the first conductive pattern 165 and the second conductive pattern 175 can act as a mask to block the dopant. As a result, the active layer ACT under the first conductive pattern 165 and the second conductive pattern 175 may not be doped and can have a crystalline structure.

Hereinafter, a display apparatus including at least one of the above-described thin film transistors will be described in detail.

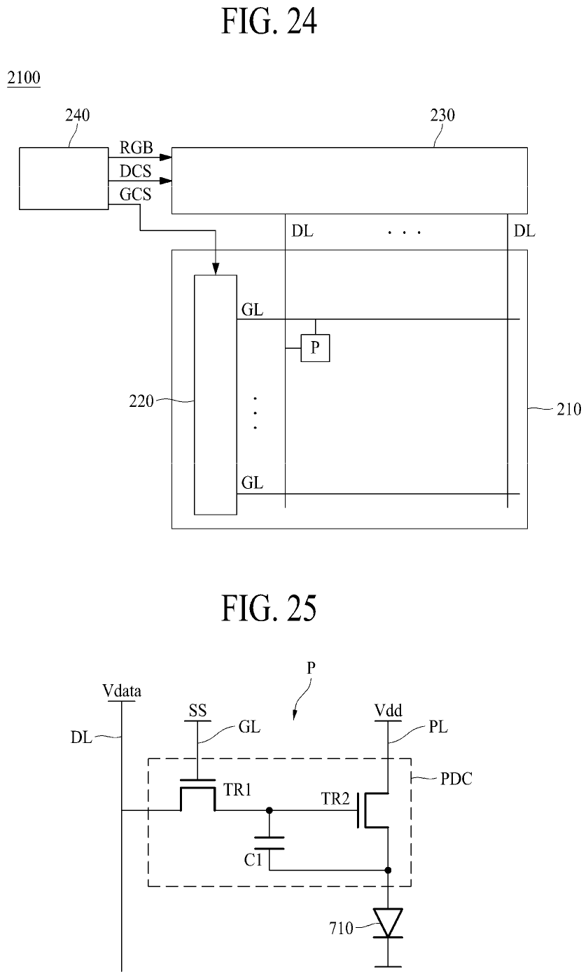

FIG. 24 is a schematic diagram of a display apparatus 2100 according to another embodiment of the present disclosure.

A display apparatus 2100 according to another embodiment of this disclosure can include a display panel 210, a gate driver 220, a data driver 230, and a control unit or controller 240.

Gate lines GL and data lines DL are disposed on the display panel 210, and pixels P are disposed at intersections of the gate lines GL and data lines DL. An image is displayed by driving the pixel P.

The controller 240 controls the gate driver 220 and the data driver 230.

The controller 240 outputs a gate control signal GCS for controlling the gate driver 220 and a data control signal DCS for controlling the data driver 230 by using a synchronization signal and a clock signal, which are supplied from an external system. Also, the controller 240 samples input image data input from the external system, realigns the sampled data and supplies the realigned digital image data RGB to the data driver 230.

The gate control signal GCS includes a gate start pulse (GSP), a gate shift clock (GSC), a gate output enable signal (GOE), a start signal (Vst), and a gate clock (GCLK). Also, control signals for controlling a shift register can be included in the gate control signal GCS.

The data control signal DCS includes a source start pulse (SSP), a source shift clock signal (SSC), a source output enable signal (SOE), and a polarity control signal (POL).

The data driver 230 supplies a data voltage to the data lines DL of the display panel 210. In detail, the data driver 230 converts the image data RGB input from the controller 240 into an analog data voltage and supplies a data voltage of one horizontal line to the data lines DL.

The gate driver 220 sequentially supplies the gate pulses (GP) to the gate lines GL for one frame. Here, one frame refers to a period in which one image is output through a display panel. In addition, the gate driver 220 supplies the gate line GL with a gate-off signal (Goff) that can turn off the switching element for the rest of the period when the gate pulse (GP) is not supplied during one frame. Hereinafter, the gate pulse (GP) and the gate-off signal (Goff) are collectively referred to as the scan signal SS (see FIG. 25).

According to an embodiment of the present disclosure, the gate driver 220 can be mounted on the substrate 110. As such, the structure in which the gate driver 220 is directly mounted on the substrate 110 is called as the Gate In Panel (GIP) structure.

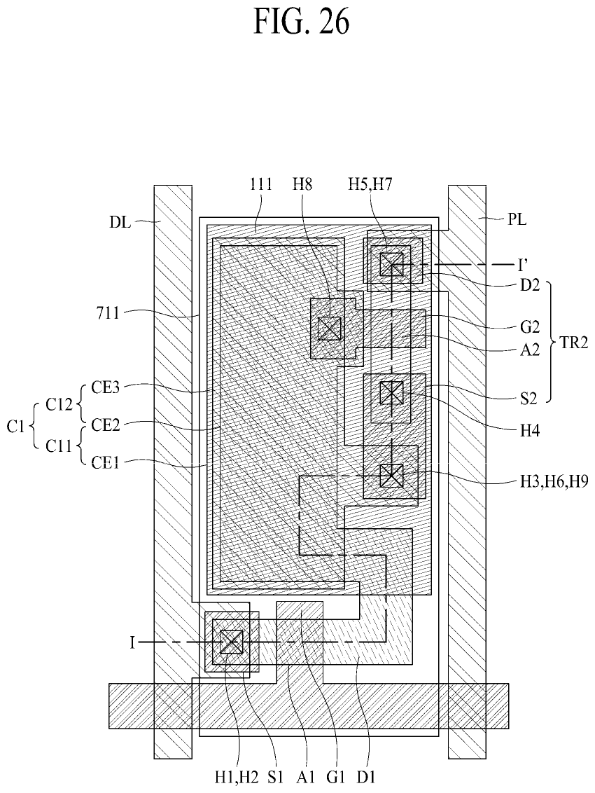

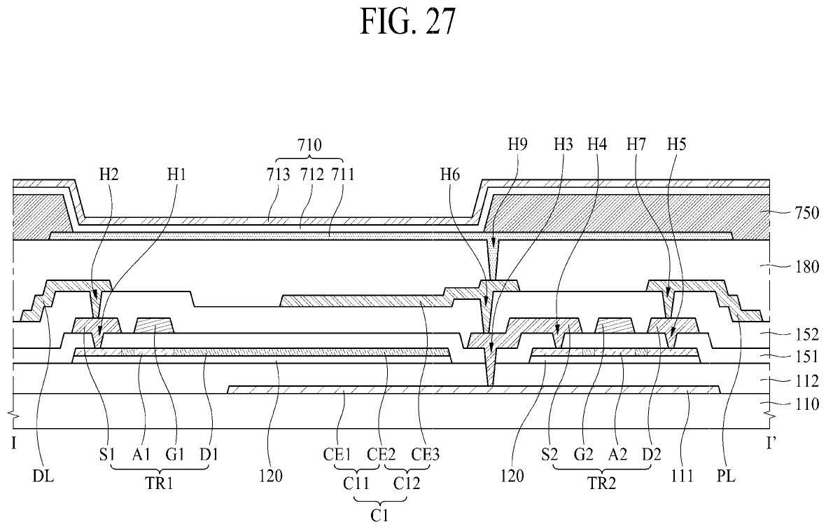

FIG. 25 is a circuit diagram of one pixel P of FIG. 24, FIG. 26 is a plan view of the pixel P of FIG. 25, and FIG. 27 is a cross-sectional view taken along I-I′ of FIG. 26 according to an embodiment of the present disclosure.

The circuit diagram of FIG. 25 is an equivalent circuit diagram of a pixel P of a display apparatus 2100 including an organic light emitting diode (OLED) as a display element 710.

The pixel P includes a display element 710 and a pixel driving part or pixel driving circuit PDC that drives the display element 710.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

A driving power line PL provides a driving voltage Vdd to the display element 710, and the second thin film transistor TR2 controls applying of the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 220 through the gate line GL, the data voltage Vdata supplied through the data line DL is supplied to a gate electrode of the second thin film transistor TR2 connected with the display element 710. The data voltage Vdata is charged in a first capacitor C1 formed between the gate electrode and a source electrode of the second thin film transistor TR2. The first capacitor C1 is a storage capacitor (Cst).

The amount of a current supplied to the organic light emitting diode (OLED), which is the display element 710, through the second thin film transistor TR2 is controlled in accordance with the data voltage Vdata, whereby gray scale values of light emitted from the display element 710 can be controlled.

Referring to FIGS. 26 and 27, the first thin film transistor TR1 and the second thin film transistor TR2 are disposed on the substrate 110.

The substrate 110 can be made of glass or plastic. Plastic having flexibility properties, for example, polyimide (PI), can be used as the substrate 110.

A light blocking layer 111 is disposed on the substrate 110. The light blocking layer 111 can have light blocking characteristics. The light blocking layer 111 can protect the active layer A2 by blocking light incident from the outside.

A buffer layer 112 is disposed on the light blocking layer 111. The buffer layer 112 is made of an insulating material and protects the active layers A1 and A2 from moisture or oxygen flowing from the outside. A portion of the light blocking layer 111 can be a first capacitor electrode CE1.

The active layer A1 of the first thin film transistor TR1 and the active layer A2 of the second thin film transistor TR2 are disposed on the buffer layer 112.

The active layers A1 and A2 can include, for example, an oxide semiconductor material. The active layers A1 and A2 can be formed of an oxide semiconductor layer made of an oxide semiconductor material. The active layers A1 and A2 can include a crystalline portion and an amorphous portion. The channel portions of the active layers A1 and A2 can have crystalline structures.

Specifically, the active layers A1 and A2 can include a first active layer 130 and an amorphous active layer 120. However, an embodiment of the present disclosure is not limited thereto, and the active layers A1 and A2 can include a barrier active layer 140.

Referring to FIGS. 26 and 27, a portion of the active layer A1 of the first thin film transistor TR1 can be conductorized to form a second capacitor electrode CE2. For example, the drain region of the first thin film transistor TR1 can extend to form the second capacitor electrode CE2.

The drain region of the first thin film transistor TR1 can serve as a drain electrode D1.

A gate insulating layer 151 is disposed on the active layers A1 and A2. The gate insulating layer 151 has insulating properties and separates the active layers A1 and A2 from the gate electrodes G1 and G2. The gate insulating layer 151 can cover the entire upper surfaces of the active layers A1 and A2.

A gate electrode G1 of the first thin film transistor TR1 and a gate electrode G2 of the second thin film transistor TR2 are disposed on the gate insulating layer 151.

The gate electrode G1 of the first thin film transistor TR1 overlaps at least a portion of the active layer A1 of the first thin film transistor TR1. The gate electrode G2 of the second thin film transistor TR2 overlaps with at least a portion of the active layer A2 of the second thin film transistor TR2.

Referring to FIGS. 26 and 27, source electrodes S1 and S2 and drain electrode D2 are disposed on the same layer as gate electrodes G1 and G2. The source electrodes S1 and S2 and the drain electrodes D1 and D2 are distinguished for convenience of explanation, and the source electrodes S1 and S2 and the drain electrodes D1 and D2 can be exchanged.

The source electrode S1 of the first thin film transistor TR1 is connected to the active layer A1 of the first thin film transistor TR1 through the first contact hole H1.

The source electrode S2 of the second thin film transistor TR2 is connected to the light blocking layer 111 through the third contact hole H3 and to the active layer A2 of the second thin film transistor TR2 through the fourth contact hole H4. The drain electrode D2 of the second thin film transistor TR2 is connected to the active layer A2 of the second thin film transistor TR2 through the fifth contact hole H5.

Referring to FIG. 26, the gate electrode G2 of the second thin film transistor TR2 is connected to the second capacitor electrode CE2 through the eighth contact hole H8. As a result, the gate electrode G2 of the second thin film transistor TR2 can be connected to the first thin film transistor TR1.

An interlayer insulating layer 152 is disposed on the gate electrodes G1 and G2, the source electrodes S1 and S2, and the drain electrode D2.

The data line DL and the driving power line PL are disposed on the interlayer insulating layer 152.

The data line DL is in contact with the source electrode S1 of the first thin film transistor TR1 through the second contact hole H2. According to another embodiment of the present disclosure, a portion of the data line DL can be referred to as a source electrode S1.

The driving power line PL contacts the drain electrode D2 of the second thin film transistor TR2 through the seventh contact hole H7. According to another embodiment of the present disclosure, a portion of the driving power line PL can be referred to as a drain electrode D2.

Referring to FIGS. 26 and 27, a third capacitor electrode CE3 is disposed on the interlayer insulating layer 152. The third capacitor electrode CE3 contacts the source electrode S2 of the second thin film transistor TR2 through the sixth contact hole H6.

The second sub-capacitor C12 and the first sub-capacitor C11 form the first capacitor C1.

The first sub-capacitor C11 can be formed by overlapping the first capacitor electrode CE1 with the second capacitor electrode CE2. The second sub-capacitor C12 can be formed by overlapping the second capacitor electrode CE2 with the third capacitor electrode CE3.

The first capacitor C1 is formed by the first sub-capacitor C11 and the second sub-capacitor C12.

The planarization layer 180 is disposed on the data line DL, the driving power line PL, and the third capacitor electrode CE3. The planarization layer 180 flattens the top of the first thin film transistor TR1 and the second thin film transistor TR2 to provide a uniform surface, and protects the first thin film transistor TR1 and the second thin film transistor TR2.

The first electrode 711 of the display element 710 is disposed on the planarization layer 180. The first electrode 711 of the display element 710 contacts the third capacitor electrode CE3 through a ninth contact hole H9 formed in the planarization layer 180. As a result, the first electrode 711 can be connected to the second source electrode S2 of the second thin film transistor TR2.

A bank layer 750 is disposed at an edge of the first electrode 711. The bank layer 750 defines a light emitting area of the display element 710.

An organic emission layer 712 is disposed on the first electrode 711, and a second electrode 713 is disposed on the organic emission layer 712. Accordingly, the display element 710 is completed. The display element 710 illustrated in FIG. 27 is an organic light emitting diode (OLED). Accordingly, the display apparatus 2100 according to an embodiment of the present disclosure is an organic light emitting display apparatus. Also, the first thin film transistor TR1 can be disposed along a first side of the display element 710 and the second thin film transistor TR2 can be disposed along a second side the display element 710 that is perpendicular to the first side.

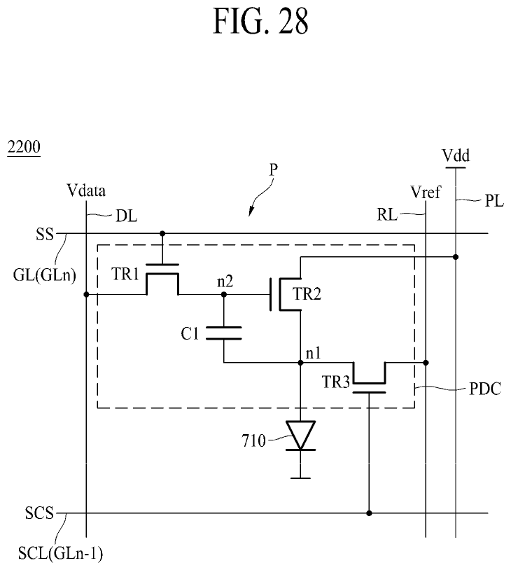

FIG. 28 is a circuit diagram of a pixel P of a display apparatus 2200 according to another embodiment of the present disclosure.

FIG. 28 is an equivalent circuit diagram of a pixel P of an organic light emitting display apparatus.

The pixel P of the display apparatus 2200 shown in FIG. 28 includes an organic light emitting diode (OLED) that is a display element 710, and a pixel driving circuit PDC for driving the display element 710. The display element 710 is connected with the pixel driving circuit PDC.

In the pixel P, signal lines DL, GL, PL, RL and SCL for supplying signals to the pixel driving circuit PDC are disposed.

The data voltage Vdata is supplied to the data line DL, the scan signal SS is supplied to the gate line GL, the driving voltage Vdd for driving the pixel is supplied to the driving power line PL, a reference voltage Vref is supplied to a reference line RL, and a sensing control signal SCS is supplied to a sensing control line SCL.

Referring to FIG. 28, assuming that a gate line of an nth pixel P is “GLn,” a gate line of a (n−1)th pixel P adjacent to the nth pixel P is “GLn−1,” and the gate line “GLn−1” of the (n−1)th pixel P serves as a sensing control line SCL of the nth pixel P.

The pixel driving circuit PDC, for example, includes a first thin film transistor TR1 (switching transistor) connected with the gate line GL and the data line DL, a second thin film transistor TR2 (driving transistor) for controlling a magnitude of a current output to the display element 710 in accordance with the data voltage Vdata transmitted through the first thin film transistor TR1, and a third thin film transistor TR3 (reference transistor) for sensing characteristics of the second thin film transistor TR2.

A first capacitor C1 is disposed between a gate electrode of the second thin film transistor TR2 and the display element 710. The first capacitor C1 is referred to as a storage capacitor (Cst).

The first thin film transistor TR1 is turned on by the scan signal SS supplied to the gate line GL to transmit the data voltage Vdata, which is supplied to the data line DL, to the gate electrode G2 of the second thin film transistor TR2.

The third thin film transistor TR3 is connected to a first node n1 between the second thin film transistor TR2 and the display element 710 and the reference line RL and thus turned on or off by the sensing control signal SCS, and senses characteristics of the second thin film transistor TR2, which is a driving transistor, for a sensing period.

A second node n2 connected with the gate electrode of the second thin film transistor TR2 is connected with the first thin film transistor TR1. The first capacitor C1 is formed between the second node n2 and the first node n1.

When the first thin film transistor TR1 is turned on, the data voltage Vdata supplied through the data line DL is supplied to the gate electrode of the second thin film transistor TR2. The data voltage Vdata is charged in the first capacitor C1 formed between the gate electrode G2 and the source electrode S2 of the second thin film transistor TR2.

When the second thin film transistor TR2 is turned on, the current is supplied to the display element 710 through the second thin film transistor TR2 in accordance with the driving voltage Vdd for driving the pixel, whereby light is output from the display element 710.

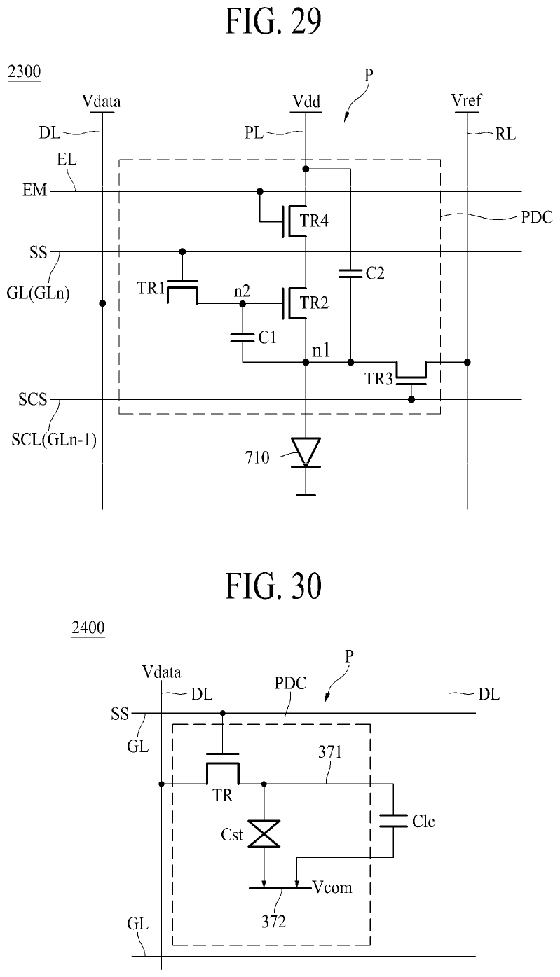

FIG. 29 is a circuit view illustrating any one pixel P of a display apparatus 2300 according to further still another embodiment of the present disclosure.

The pixel P of the display apparatus 2300 shown in FIG. 29 includes an organic light emitting diode (OLED) that is a display element 710, and a pixel driving circuit PDC for driving the display element 710. The display element 710 is connected with the pixel driving circuit PDC.

The pixel driving circuit PDC includes thin film transistors TR1, TR2, TR3 and TR4.

In the pixel P, signal lines DL, EL, GL, PL, SCL and RL for supplying a driving signal to the pixel driving circuit PDC are disposed.

In comparison with the pixel P of FIG. 28, the pixel P of FIG. 29 further includes an emission control line EL. An emission control signal EM is supplied to the emission control line EL.

Also, the pixel driving circuit PDC of FIG. 29 further includes a fourth thin film transistor TR4 that is an emission control transistor for controlling a light emission timing of the display element 710 by the second thin film transistor TR2, in comparison with the pixel driving circuit PDC of FIG. 28.

Referring to FIG. 29, assuming that a gate line of an nth pixel P is “GLn,” a gate line of a (n−1)th pixel P adjacent to the nth pixel P is “GLn−1,” and the gate line “GLn−1” of the (n−1)th pixel P serves as a sensing control line SCL of the nth pixel P.

A first capacitor C1 is positioned between the gate electrode of the second thin film transistor TR2 and the display element 710. A second capacitor C2 is positioned between one of terminals of the fourth thin film transistor TR4, to which a driving voltage Vdd is supplied, and one electrode of the display element 710.

The first thin film transistor TR1 is turned on by the scan signal SS supplied to the gate line GL to transmit the data voltage Vdata, which is supplied to the data line DL, to the gate electrode of the second thin film transistor TR2.

The third thin film transistor TR3 is connected to the reference line RL and thus turned on or off by the sensing control signal SCS, and senses characteristics of the second thin film transistor TR2, which is a driving transistor, for a sensing period.

The fourth thin film transistor TR4 transfers the driving voltage Vdd to the second thin film transistor TR2 in accordance with the emission control signal EM, or shields the driving voltage Vdd. When the fourth thin film transistor is turned on, a current is supplied to the second thin film transistor TR2, whereby light is output from the display element 710.

The pixel driving circuit PDC according to further still another embodiment of the present disclosure can be formed in various structures in addition to the above-described structure. The pixel driving circuit PDC, for example, can include five or more thin film transistors.

FIG. 30 is a circuit view illustrating a pixel P of a display apparatus 2400 according to further still another embodiment of the present disclosure. The display apparatus 2400 of FIG. 30 is a liquid crystal display apparatus.

The pixel P of the display apparatus 2400 shown in FIG. 30 includes a pixel driving circuit PDC, and a liquid crystal capacitor Clc connected with the pixel driving circuit PDC. The liquid crystal capacitor Clc corresponds to a display element.

The pixel driving circuit PDC includes a thin film transistor TR connected with the gate line GL and the data line DL, and a storage capacitor Cst connected between the thin film transistor TR and a common electrode 372. The liquid crystal capacitor Clc is connected with the storage capacitor Cst in parallel between the thin film transistor TR and the common electrode 372.

The liquid crystal capacitor Clc charges a differential voltage between a data signal supplied to a pixel electrode 371 through the thin film transistor TR and a common voltage Vcom supplied to the common electrode 372, and controls a light-transmissive amount by driving liquid crystals in accordance with the charged voltage. The storage capacitor Cst stably maintains the voltage charged in the liquid crystal capacitor Clc.

According to the present disclosure, the following advantageous effects can be obtained.

According to an embodiment of the present disclosure, the active layer has both a crystalline portion and an amorphous portion, and thus the thin film transistor can have excellent reliability and excellent electrical properties. The display apparatus according to an embodiment of the present disclosure including such a thin film transistor can have excellent display performance, a longer lifespan and excellent reliability.

According to an embodiment of this disclosure, a thin film transistor including an active layer having both a crystalline portion and an amorphous portion can be easily manufactured by using at least one of a gate electrode, a source electrode, a drain electrode, and a conductive pattern as a mask during a doping process, which reduces manufacturing time and costs, and improves production yields.

It will be apparent to those skilled in the art that the present disclosure described above is not limited by the above-described embodiments and the accompanying drawings and that various substitutions, modifications and variations can be made in the present disclosure without departing from the spirit or scope of the disclosures.

What is claimed is:

1. A thin film transistor comprising:
an active layer;
a gate electrode at least partially overlapping with the active layer; and
a source electrode and a drain electrode spaced apart from each other and connected to the active layer, respectively;
wherein the active layer includes a first active layer, and the first active layer includes:
a channel overlapping with the gate electrode;
a first connection portion connected to a first side of the channel; and
a second connection portion connected to a second side of the channel portion,
wherein the channel has a crystalline structure,
wherein the first connection portion includes a first amorphous portion contacting the channel, and
wherein the second connection portion includes a second amorphous portion contacting the channel.

2. The thin film transistor of claim 1, wherein the first active layer includes:
an oxide semiconductor material; and
a crystallization control element dispersed in the oxide semiconductor material, and
wherein the crystallization control element includes at least one of beryllium (Be), boron (B), carbon (C), aluminum (Al), silicon (Si), iron (Fe), calcium (Ca), tin (Sn), titanium (Ti), tantalum (Ta), vanadium (V), yttrium (Y), zirconium (Zr), hafnium (Hf), lanthanum (La), and germanium (Ge).

3. The thin film transistor of claim 2, wherein the crystallization control element has a content of 0.1 to 10 atom % (at %) based on a total number of atoms in the first active layer excluding oxygen.

4. The thin film transistor of claim 2, wherein the oxide semiconductor material includes at least one of an IZO (InZnO)-based oxide semiconductor material, an IGO (InGaO)-based oxide semiconductor material, an IGZO (InGaZnO)-based oxide semiconductor material, an ITO (InSnO)-based oxide semiconductor material, an IGZTO (InGaZnSnO)-based oxide semiconductor material, an ITZO (InSnZnO)-based oxide semiconductor material, a ZnO-based oxide semiconductor material, and a FIZO (FeInZnO)-based oxide semiconductor material.

5. The thin film transistor of claim 1, wherein the channel of the first active layer includes at least one crystal structure selected from a cubic crystal structure, a Bixbyite crystal structure, a cubic Bixbyite crystal structure, a spinel crystal structure, a hexagonal crystal structure, and a Wurtzite crystal structure.

6. The thin film transistor of claim 1, wherein the channel of the first active layer includes a crystal plane having an inclination angle of 30° to 60° with respect to a horizontal plane.

7. The thin film transistor of claim 1, wherein the first connection portion of the first active layer further includes a first crystalline portion contacting the first amorphous portion, and
wherein the second connection portion of the first active layer further includes a second crystalline portion contacting the second amorphous portion.

8. The thin film transistor of claim 7, wherein the first amorphous portion is disposed between the channel and the first crystalline portion,
wherein the second amorphous portion is disposed between the channel and the second crystalline portion, and
wherein the first crystalline portion and the second crystalline portion have a same crystal structure as the channel.

9. The thin film transistor of claim 7, wherein the first connection portion further includes a third amorphous portion contacting the first crystalline portion,
wherein the first crystalline portion is disposed between the first amorphous portion and the third amorphous portion,
wherein the second connection portion further includes a fourth amorphous portion contacting the second crystalline portion, and
wherein the second crystalline portion is disposed between the second amorphous portion and the fourth amorphous portion.

10. The thin film transistor of claim 7, wherein the source electrode is disposed on a same layer as the gate electrode, and the source electrode is connected to the first connection portion,
wherein the source electrode overlaps with the first crystalline portion and the source electrode does not overlap with the first amorphous portion,
wherein the drain electrode is disposed on a same layer as the gate electrode, and the drain electrode is connected to the second connection portion, and
wherein the drain electrode overlaps with the second crystalline portion and the drain electrode does not overlap with the second amorphous portion.

11. The thin film transistor of claim 7, further comprising:
a first conductive pattern disposed on the first crystalline portion; and
a second conductive pattern disposed on the second crystalline portion,
wherein the first conductive pattern does not overlap with the first amorphous portion, and
wherein the second conductive pattern does not overlap with the second amorphous portion.

12. The thin film transistor of claim 1, wherein the active layer further includes an amorphous active layer overlapping with the first active layer, the amorphous active layer contacting the first active layer,
wherein the amorphous active layer includes:
a channel overlapping with the gate electrode;
a first connection portion connected to a first side of the channel of the amorphous active layer; and
a second connection portion connected to a second side of the channel of the amorphous active layer, and
wherein each of the channel, the first connection portion and the second connection portion of the amorphous active layer has an amorphous structure.

13. The thin film transistor of claim 12, wherein a carrier concentration of the channel of the amorphous active layer is lower than a carrier concentration of the channel of the first active layer.

14. The thin film transistor of claim 12, wherein the amorphous active layer has a thickness of 1 nm to 5 nm.

15. The thin film transistor of claim 12, wherein the amorphous active layer includes:
a first amorphous active layer contacting the first active layer; and
a second amorphous active layer contacting the first active layer disposed opposite to the first amorphous active layer.

16. The thin film transistor of claim 12, wherein the active layer further includes a barrier active layer disposed opposite to the amorphous active layer, the barrier active layer overlapping with and contacting the first active layer.

17. The thin film transistor of claim 1, wherein the active layer further includes a barrier active layer overlapping with the first active layer and contacting the first active layer,
wherein the barrier active layer includes:
a channel overlapping with the gate electrode;
a first amorphous portion connected to a first side of the channel of the barrier active layer; and
a second amorphous portion connected to a second side of the channel of the barrier active layer;
wherein the channel of the barrier active layer has a crystalline structure,
wherein each of the first amorphous portion and the second amorphous portion of the barrier active layer has an amorphous structure, and
wherein a carrier concentration of the channel portion of the barrier active layer is lower than a carrier concentration of the channel portion of the first active layer.

18. The thin film transistor of claim 17, wherein the barrier active layer has a thickness of 5 nm to 30 nm.

19. The thin film transistor of claim 17, wherein the barrier active layer includes:
a first barrier active layer contacting the first active layer; and
a second barrier active layer contacting the first active layer, the second barrier active layer being disposed opposite to the first barrier active layer.

20. The thin film transistor of claim 17, wherein the barrier active layer further includes a first crystalline portion contacting the first amorphous portion of the barrier active layer,
wherein the first amorphous portion of the barrier active layer is disposed between the channel of the barrier active layer and the first crystalline portion of the barrier active layer,
wherein the barrier active layer further includes a second crystalline portion contacting the second amorphous portion of the barrier active layer, and
wherein the second amorphous portion of the barrier active layer is disposed between the channel of the barrier active layer and the second crystalline portion of the barrier active layer.

21. A thin film transistor substrate comprising:
a light blocking layer on a base substrate;
the thin film transistor of claim 1 disposed on the light blocking layer; and
a capacitor connected to the light blocking layer,
wherein the capacitor includes a first capacitor electrode and a second capacitor electrode,
wherein the first capacitor electrode is integrally formed with the light blocking layer, and
wherein the second capacitor electrode is disposed on a same layer as the first active layer.

22. The thin film transistor substrate of claim 21, wherein the second capacitor electrode includes a layer having an amorphous structure or a crystalline structure.

23. A display apparatus comprising a display panel and the thin film transistor of claim 1.

24. A method for manufacturing a thin film transistor, the method comprising:
forming an active layer on a substrate;
forming a gate insulating layer on the active layer;
forming a gate electrode on the gate insulating layer; and
selectively doping the active layer with a dopant,
wherein the forming the active layer includes:
forming a first oxide semiconductor material layer using a crystalline oxide semiconductor material,
forming an active pattern by patterning the first oxide semiconductor material layer, and
forming a first active layer having a crystalline active pattern by heat-treating the active pattern, and
wherein a region doped with the dopant in the active layer has an amorphous structure.

25. The method of claim 24, wherein the forming the active layer includes:
forming a first amorphous oxide semiconductor portion and a second amorphous oxide semiconductor portion on opposite sides of the crystalline active pattern;
forming a first conductive pattern disposed on the first amorphous oxide semiconductor portion; and
forming a second conductive pattern disposed on the second amorphous oxide semiconductor portion,
wherein the first conductive pattern and the second conductive pattern include a transparent conductive oxide.

26. The method of claim 25, wherein the forming the active layer further includes:
passing a dopant through the first and second conductive patterns for forming the first and second amorphous oxide semiconductor portions.

27. The method of claim 24, wherein the first oxide semiconductor material layer includes an oxide semiconductor material and a crystallization control element.

28. The method of claim 27, wherein the forming the active layer further includes forming an amorphous oxide semiconductor material layer using an amorphous oxide semiconductor material.

29. The method of claim 27, wherein the forming of the active layer further includes forming a barrier oxide semiconductor material layer using a crystalline oxide semiconductor material.

30. A thin film transistor comprising:
a gate electrode disposed on a substrate; and
a first active layer overlapping with the gate electrode, the first active layer including:
a first amorphous oxide semiconductor portion, a second amorphous oxide semiconductor portion, and
a crystalline oxide semiconductor channel disposed between the first amorphous oxide semiconductor portion and the second amorphous oxide semiconductor portion.

31. The thin film transistor of claim 30, further comprising:
a first conductive pattern disposed on the first amorphous oxide semiconductor portion; and
a second conductive pattern disposed on the second amorphous oxide semiconductor portion,
wherein the first conductive pattern and the second conductive pattern include a transparent conductive oxide.

32. The thin film transistor of claim 30, wherein the crystalline oxide semiconductor channel has a higher electrical resistance than both of the first amorphous oxide semiconductor portion and the second amorphous oxide semiconductor portion.

33. The thin film transistor of claim 30, further comprising:
a source electrode;
a first crystalline oxide semiconductor portion connected to the source electrode;
a drain electrode; and
a second crystalline oxide semiconductor portion connected to the drain electrode;
wherein the first amorphous oxide semiconductor portion is disposed between the first crystalline oxide semiconductor portion and the crystalline oxide semiconductor channel, and
wherein the second amorphous oxide semiconductor portion is disposed between the second crystalline oxide semiconductor portion and the crystalline oxide semiconductor channel.

34. The thin film transistor of claim 30, wherein the first active layer includes two or more layers.

35. The thin film transistor of claim 30, wherein the crystalline oxide semiconductor channel includes at least one of a 211 crystal plane, a 222 crystal plane, and a 400 crystal plane.

36. The thin film transistor of claim 35, wherein a number of 400 crystal planes within the crystalline oxide semiconductor channel is greater than a number of 211 crystal planes within the crystalline oxide semiconductor channel, and a number of 222 crystal planes within the crystalline oxide semiconductor channel is greater than the number of 400 crystal planes within the crystalline oxide semiconductor channel.

37. The thin film transistor of claim 30, wherein the crystalline oxide semiconductor channel includes at least one of a cubic crystal structure, a Bixbyite crystal structure, a cubic Bixbyite crystal structure, a spinel crystal structure, a hexagonal crystal structure, and a Wurtzite crystal structure.

38. The thin film transistor of claim 30, wherein both of the first amorphous oxide semiconductor portion and the second amorphous oxide semiconductor portion include a dopant that is not present in the crystalline oxide semiconductor channel.

39. The thin film transistor of claim 30, wherein the crystalline oxide semiconductor channel includes a crystallization control element, and
wherein the crystallization control element includes at least one of beryllium (Be), boron (B), carbon (C), aluminum (Al), silicon (Si), iron (Fe), calcium (Ca), tin (Sn), titanium (Ti), tantalum (Ta), vanadium (V), yttrium (Y), zirconium (Zr), hafnium (Hf), lanthanum (La), and germanium (Ge).
